(19) United States
(12) Patent Application Publication
(10) Pub. No.: US 2025/0290194 A1
(43) Pub. Date: Sep. 18, 2025

(54) Two-Dimensional Materials, Their Composite Thin Films, and the Formation Thereof

(71) Applicant: Carnegie Mellon University, Pittsburgh, PA (US)

(72) Inventors: Chengchao Xu, Pittsburgh, PA (US); Jian-Gang Zhu, Pittsburgh, PA (US); David E. Laughlin, Pittsburgh, PA (US); Bollapragada Varaprasad, Pittsburgh, PA (US); Brandon Reese, Pittsburgh, PA (US)

(21) Appl. No.: 19/080,129

(22) Filed: Mar. 14, 2025

Related U.S. Application Data
(60) Provisional application No. 63/565,340, filed on Mar. 14, 2024.

(51) Int. Cl. C23C 14/34; C23C 14/06; C23C 14/14

(52) U.S. Cl. CPC C23C 14/3464; C23C 14/0647; C23C 14/14

(57) ABSTRACT

Systems and processes described herein are for forming a material by applying a magnetic material and a boundary material to the substrate; and while applying the magnetic material to the substrate and the boundary material to the substrate, applying a bias voltage to at least the boundary material to form a two-dimensional material between portions of the magnetic material. The material includes the magnetic material and a two-dimensional material confirming to the magnetic material or other material.

### CLAIM OF PRIORITY

This application claims priority to U.S. Patent Application Ser. No. 63/565,340, filed on Mar. 14, 2024, the entire contents of which are hereby incorporated by reference.

### BACKGROUND

Two-dimensional (2D) materials (2DMs) include a class of crystalline nanomaterials whose atomic or molecular structures are confined to a single plane in a thickness of only one or a few atoms. Graphene is a common 2D material. Commonly within the monolayer of 2D materials, the atoms are bound by strong covalent bonds, whereas the 2DM layers are held together by weak van der Waals forces to form multilayer structures. The low-dimensional nature renders unique physical properties to the 2D materials distinct from their bulk counterparts, including exceptional mechanical strength, high flexibility, high electrical conductivity, and tailorable optical properties. Despite their immense potential advantages, practical applications of 2D materials often encounter challenges, such as limitations in processability. Common top-down methods like mechanical exfoliation can be low yield and are not scalable for integration into device architectures. While some bottom-up methods like chemical vapor deposition (CVD) are highly scalable, these methods remain complex, expensive, and the choice of underlayer is limited.

Nanocomposite structures can harness the potential of 2D materials. Nanocomposites incorporate 2D materials with other materials, typically at the nanoscale, to create materials with synergistic properties. Depending on the desired properties and applications, 2D materials can be incorporated with polymers, nanoparticles or other 2D materials. Scalable fabrication of 2D material nanocomposite structures remains challenging.

### SUMMARY

This disclosure describes a process to form 2D crystalline materials with a bottom-up method of depositing single-layer or multilayer 2D crystalline materials through bias sputtering at high temperatures. The 2D crystalline materials can include materials such as hexagonal boron nitride (h-BN), borophene, graphene, transition metal dichalcogenides (TMDs) and so forth. This disclosure further describes various composite thin films comprising 2D materials and other materials and the processes for formation of the thin films. The deposition method can be based on sputter deposition, enabling a highly scalable and economic process to form the 2D materials.

The processes described herein enable formation of columnar magnetic grains having large aspect ratios. In an example, the process includes deposition of a granular nanocomposite thin film of L1₀-ordered iron-platinum (FePt) grains with 2DMs as the grain boundary materials to produce well-separated, tall and columnar FePt grains. This composite nanogranular thin film can be used as a recording media for heat-assisted magnetic recording (HAMR) technology. The boundary material is thermally insulating and non-magnetic.

The process for depositing 2D materials onto substrates can include a sputtering technique. By applying a moderate substrate bias voltage and maintaining adequately high substrate temperatures during deposition (as subsequently described in further detail), crystalline 2D materials are formed with minimized components of amorphous phases. This deposition method is versatile for producing various composite thin films comprising 2D materials and other materials.

The 2DMs can form a recording material as follows. An underlayer of appropriate crystalline lattice structures (such as MgO, or MgO+TiO) is sputtered onto a substrate with appropriate seed layers and heat sinking layers. The underlayer facilitates the appropriate crystalline orientation and atomic ordering of the iron-platinum layer to be deposited subsequently after. Next, a thin (less than 1 nm) magnetic material, such as iron-platinum layer, is sputtered onto the underlayer to form the nucleation sites for the formation of iron-platinum grains. This process is then followed by sputtering iron-platinum and boron nitride materials simultaneously, either by co-sputtering with separate iron-platinum and boron nitride targets or by a composite target that consists of both iron-platinum and boron nitride. During this stage of the process, the nucleated magnetic grains continue to grow in both size and height while boron nitride material is in amorphous phase, surrounding the individual magnetic grains.

When the grain growth of the magnetic material reaches the desired size (or diameter), an appropriate bias voltage is applied to the substrate. The bias voltage causes the subsequent growth of the boron nitride to form hexagonal crystalline 2D sheet with its plane conforming to the side wall of the magnetic grains. The crystalline planes (e.g., honeycomb sheets) of the grain boundary material are approximately perpendicular to the substrate, as described herein, and circumference individual magnetic grains. The crystalline layers of the grain boundary material cause the magnetic grains to grow vertically away from the substrate without further expansion of their diameters (columnar growth). This is because the crystalline layers of the grain boundary material are relatively incompressible. The grain boundary material, when amorphous (e.g., when no voltage bias is applied), is relatively pliable (e.g., squeezable) by the growth of the magnetic grains (e.g., Fe—Pt grains). The diameter of the grains can be precisely tuned by applying the bias voltage to the boundary material to from the rigid, vertically oriented crystalline planes of the grain boundary material around the grains precisely when the desired grain diameter is achieved, causing approximately vertical grain boundaries. The resulting material has high separation between the grains and strong thermal insulation and magnetic insulation between the grains.

The two-dimensional materials can be formed by sputtering onto a substrate with appropriate underlayer, or underlayers. For example, for thin film or recording media applications, the two-dimensional materials can be co-sputtered onto a substrate with the magnetic material (e.g., FePt) configured for forming the magnetic grains of the recording medium. In another example, the two-dimensional materials can be sputtered onto structures or wires on a substrate formed from lithographic or other processes. The two-dimensional material can form a filler material configured to conduct heat away from the structures or wires along the crystalline sheets of the two-dimensional material. For example, the filler material can be part of an integrated circuit (IC), and the two-dimensional material can conduct heat to an edge of the IC or to a heat sink of the IC for thermal management of the IC. In another example, the two-dimensional material is formed on a substrate by sputtering under a bias voltage without another material present.

The materials and processes described herein can enable one or more of the following advantages. Sputtering the two-dimensional material is more scalable for manufacturing and less expensive than chemical vapor deposition (CVD). The two-dimensional material can be formed around or with other materials or structures such that the crystalline sheets of the two-dimensional material conform to or surround the other structures or materials. In magnetic recording media applications, the bias voltage can be selectively applied to precisely tune a diameter of the magnetic grains with the onset of forming the two-dimensional material in the grain boundaries.

A graded deposition process for FePt-(h-BN) nanogranular thin films described herein improves microstructures for 2DMs, achieving high-aspect-ratio (e.g., AR ˜2.5) columnar FePt grains with a small average diameter (e.g., ˜6.4 nanometers), separated by perpendicular multilayer h-BN nanosheets in grain boundaries. The microstructural controls enabled by the sputtering processes described herein can significantly improve thermal properties and magnetic characteristics (e.g., for HAMR media applications) or other magnetic recording technologies.

The processes described herein enable the formation of recording media with columnar magnetic grains that have a large aspect ratio. Specifically, the grains can be narrow in diameter (e.g., 4 nanometers (nm) to 10 nanometers) while having a sufficient height (e.g., 0.5 nm or more) to cause the grains to have a volume that is useful for magnetizing to a given state and remain magnetized in that state. The columnar magnetic grains are separated by a thermally insulating and non-magnetic boundary that assists formation of the columnar grains. In an example, boron nitride (BN) forms the boundary layer.

The high grain aspect ratio enabled by the columnar growth of the process gives rise to stronger magnetic signal field produced by recorded magnetic transitions, thereby enhancing the recording signal level. The high grain aspect ratio also enables smaller grain diameters, yields lower medium noise. The overall increase of signal-to-noise ratio gives rise to higher area recording density capability.

The materials and processes described herein may allow for significantly reduced power consumption of memory and may minimize switching current distribution.

The sputtered hexagonal boron-nitride layers enable highly anisotropic thermal conduction. Thermal conductivity within each crystalline honeycomb plane is extremely high due to the crystalline bonds structure whereas the thermal conductivity between the adjacent crystalline planes is extremely low. The poor thermal conductivity between adjacent boron-nitride planes is caused by the weak across plane interaction that is van der Waals force in nature.

Since the invention forms a film microstructure in which crystalline hexagonal boron-nitride layers encircle individual magnetic grains, the thermal conduction between adjacent magnetic grains need to cross different boron-nitride crystalline planes. The poor thermal conductivity across the boron-nitride crystalline planes give rise to good thermal insulation between adjacent magnetic grains. In consequence, the formed film is capable of supporting high thermal gradient needed for reaching high recording area density capability.

The materials and processes described herein may allow for improved thermal management for integrated circuits or other devices. For example, using sputtered hexagonal crystalline boron-nitride as filling materials for the metal layers in integrated circuits enables excellent heat dissipation along the crystalline planes due to the extremely high thermal conductivity along the planes. The in crystalline plane thermal conductivity of hexagonal boron-nitride is one to two orders of magnitude higher than currently used filling material such as SiO₂.

In some implementations, a multilayer thin film includes an alternating stack of 2D materials layers and other material layers, which can exhibit superlattice nanostructures with sharp, flat, and smooth interfaces. The (002) texture of 2D materials induced by the bias-sputtering process forms weak-bonded van der Waals interfaces with other materials, rendering unique physical properties to the multilayer films as described herein. For example, an ultralow cross-plane thermal conductivity is exhibited in the [h-BN(002)/FePt] multilayer films. In another example, a nanocomposite formed using the bias-sputtering process includes FePt-2DM nanogranular thin films.

In an aspect, a fabrication of multilayer thin films comprises an alternating stack of sub-0 nm-thick layers of 2D materials and other materials, resulting in superlattice nanostructures with sharp and smooth interfaces. One example of the multilayer films [FePt/h-BN]×N is detailed below. The h-BN nanosheets formed in between two FePt layers develop a (002) texture. Namely, these h-BN monolayers are all parallel to the film plane. The resulting superlattice structure with high density of [FePt/h-BN(002)] van der Waals interfaces render an ultralow thermal conductivity normal to the film.

One or more of the foregoing advantages are enabled by one or more of the following implementations and aspects.

In an aspect, a material includes a magnetic material forming a plurality of grains; and a two-dimensional material between at least two grains of the plurality of grains. In some implementations, the two-dimensional material comprises a crystalline structure. In some implementations, the two-dimensional material comprises a single layer having the crystalline structure. In some implementations, the two-dimensional material comprises a plurality of layers each having the crystalline structure. In some implementations, the crystalline structure comprises a hexagonal boron-nitride (h-BN) structure. In some implementations, a first h-BN volume fraction is reduced near a top a grain of the plurality relative to a second h-BN volume fraction near a bottom of the grain of the plurality. In some implementations, the first h-BN volume fraction is approximately 22.6 vol % and wherein the second h-BN volume fraction is approximately 24.5 vol %. In some implementations, the first h-BN volume fraction is approximately 16 vol % and wherein the second h-BN volume fraction is approximately 22 vol %. In some implementations, the first h-BN volume fraction is approximately 18 vol % and wherein the second h-BN volume fraction is approximately 22 vol %. In some implementations, the two-dimensional material comprises boron nitride and wherein the magnetic material comprises iron-platinum.

In some implementations, the magnetic material and the two-dimensional material form a thin film having a thickness of 6.0 nanometers. In some implementations, at least one grain of the plurality of grains has a height to diameter aspect ratio (h/D) of at least 2.5. In some implementations, at least one grain of the plurality of grains has a height to diameter aspect ratio (h/D) of at least 1.5. In some implementations, the plurality of grains have a center-to-center pitch distance of approximately 8.3±1.9 nm. In some implementations, the plurality of grains have a grain areal density of roughly 1.969×10⁴ per square micrometer (μm⁻²). In some implementations, at least one grain of the plurality of grains has a diameter of 4-10 nm and a length of at least 0.5 nm. In some implementations, the magnetic material and the two-dimensional material form a FePt-(h-BN) thin film. In some implementations, the magnetic material and the two-dimensional material form a FePt-(h-BN(002)) thin film. In some implementations, the magnetic material and the two-dimensional material form a FePt-(h-BN(001)) thin film. In some implementations, the magnetic material and the two-dimensional material form a multilayer FePt-(h-BN)×N thin film.

In some implementations, the magnetic material forms L1₀ FePt grains. In some implementations, the magnetic material and the two-dimensional material together have an effective thermal conductivity of 0.6±0.05 W/(mK). In some implementations, the two-dimensional material comprises borophene. In some implementations, the two-dimensional material comprises graphene. In some implementations, the two-dimensional material comprises transition metal dichalcogenides (TMDs). In some implementations, the two-dimensional material forms at least 4 to 6 nanosheets that conform to at least one grain of the plurality of grains. In some implementations, the two-dimensional material forms at least 6 to 8 nanosheets that conform to at least one grain of the plurality of grains. In some implementations, the two-dimensional material forms up to 10 nanosheets that conform to at least one grain of the plurality of grains.

In some implementations, the material includes an underlayer selected from: MgO (001), Cr (001), and amorphous Ta (a-Ta).

In some implementations, the material includes a nucleation layer of magnetic material onto which the plurality of grains and the two-dimensional material between the grains are formed.

In some implementations, the plurality of grains and the two-dimensional material form a FePt-(h-BN) film that is at least 5 nm tall, wherein grains of the plurality of grains comprise unbroken, columnar grains, and wherein the two-dimensional material comprises one or more nanosheets that conform the grains of the plurality of grains.

In some implementations, the material includes a plurality of layers of the magnetic material and the two-dimensional material. In some implementations, at least two layers of the plurality of layers are twisted with respect to each other. In some implementations, the at least two layers of the plurality of layers are twisted at approximately 2° with respect to each other.

In some implementations, the magnetic material and the two-dimensional material form a superlattice nanostructure with sharp interfaces of h-BN(002)/FePt(002).

In some implementations, the material includes a substrate on which the magnetic material and the two-dimensional material are sputtered. In some implementations, the substrate is curved. In some implementations, the substrate is selected from one of an amorphous metal, a crystalline metal, a ceramic, a semiconductor, and a composite.

In some implementations, the magnetic material comprises FePt.

In some implementations, the material includes a substrate comprising one or more lithography-patterned structures, wherein the magnetic material and the two-dimensional material are applied to the lithography-patterned structures.

In an aspect, a memory is formed from the material of any of the foregoing implementations or aspects. In some implementations, the memory comprises a magnetoresistive random access memory (MRAM). In some implementations, the memory comprises a perpendicular spin transfer torque (STT) MRAM memory element.

In an aspect, a process for forming a material includes obtaining a substrate; applying a magnetic material and a boundary material to the substrate; and while applying the magnetic material to the substrate and the boundary material to the substrate, applying a bias voltage to at least the boundary material to form a two-dimensional material between portions of the magnetic material.

In some implementations, applying the magnetic material to the substrate and the boundary material to the substrate comprises co-sputtering the magnetic material and the boundary material onto the substrate, wherein the boundary material forms the two-dimensional material when co-sputtered onto the substrate while the bias voltage is applied.

In some implementations, the process includes co-sputtering a set of layers of the magnetic material and the boundary material that forms the two-dimensional material onto the substrate, each subsequent layer after a first layer of the set of layers being co-sputtered onto a previous layer; and altering, for at least one layer, at least one sputtering condition during co-sputtering of the magnetic material and the boundary material. In some implementations, altering the at least one sputtering condition during co-sputtering of the magnetic material and the boundary material onto the substrate comprises gradually altering the at least one sputtering condition per layer as multiple layers of the magnetic material and the boundary material are co-sputtered onto the substrate.

In some implementations, the process includes gradually altering two or more sputtering conditions per layer as multiple layers of the magnetic material and the boundary material are co-sputtered onto the substrate.

In some implementations, altering the at least one sputtering condition during co-sputtering of the magnetic material and the boundary material onto the substrate comprises reducing a volume % of the boundary material for at least one subsequent layer relative to the first layer.

In some implementations, altering the at least one sputtering condition during co-sputtering of the magnetic material and the boundary material onto the substrate comprises reducing a volume % of the boundary material for at least one subsequent layer relative to the first layer while reducing a temperature of the substrate.

In some implementations, altering the at least one sputtering condition during co-sputtering of the magnetic material and the boundary material onto the substrate comprises reducing a temperature of the substrate for at least one subsequent layer relative to the first layer.

In some implementations, the process includes applying the magnetic material and the boundary material to the substrate for a period of time without applying the bias voltage; and after the period of time, while applying the magnetic material to the substrate and the boundary material to the substrate, applying the bias voltage to at least the boundary material. In some implementations, the boundary material includes an amorphous material corresponding to the period of time without applying the bias voltage.

In some implementations, the process includes tuning a structure of the magnetic material based on a length of the period of time. In some implementations, the magnetic material forms columnar grains having a first diameter when the period of time is a first length of time, and wherein the magnetic material forms columnar grains having a second diameter when the period of time is a second length of time. In some implementations, the first diameter is larger than the second diameter when the first length of time is longer than the second length of time.

In some implementations, applying the bias voltage to at least the boundary material to form the two-dimensional material between portions of the magnetic material comprises applying a direct current bias voltage.

In some implementations, applying the bias voltage to at least the boundary material to form the two-dimensional material between portions of the magnetic material comprises applying an alternative current bias voltage.

In some implementations, the bias voltage is between 5 and 20 volts. In some implementations, the bias voltage is between 1 and 100 volts.

In some implementations, the process includes applying a temperature to heat the magnetic material and the boundary material when applying the magnetic material and the boundary material to the substrate.

In some implementations, the temperature is between 300° C. to 850° C., inclusive. In some implementations, the temperature is reduced from a higher temperature to a lower temperature as additional magnetic material and boundary material are applied. In some implementations, the bias voltage comprises a negative substrate bias voltage with respect to a common ground connected to a sputtering chamber.

In some implementations, the process includes applying the magnetic material and the boundary material to the substrate over lithography-patterned structures.

In an aspect, a material includes a length material forming a structure; and a two-dimensional material proximate to the length of the material conducting metal forming the structure. In some implementations, the structure includes a wire. In some implementations, the wire is part of an integrated circuit (IC).

In some implementations, the material includes a substrate comprising one or more lithography-patterned structures including the structure, the two-dimensional material is applied to the lithography-patterned structures. In some implementations, the substrate is part of an integrated circuit (IC). In some implementations, the two-dimensional material comprises a crystalline structure. In some implementations, the two-dimensional material comprises a single layer having the crystalline structure. In some implementations, the two-dimensional material comprises a plurality of layers each having the crystalline structure. In some implementations, the crystalline structure comprises a hexagonal boron-nitride (h-BN) structure.

In some implementations, the two-dimensional material comprises borophene. In some implementations, the two-dimensional material comprises graphene. In some implementations, the two-dimensional material comprises transition metal dichalcogenides (TMDs).

In an aspect, a process includes forming a two-dimensional material by sputtering a crystalline-forming material onto a substrate while applying a bias voltage to the substrate. In some implementations, the crystalline-forming material comprises boron nitride.

In some implementations, the process includes co-sputtering a magnetic material and the crystalline-forming material onto the substrate, wherein the crystalline-forming material forms the two-dimensional material when co-sputtered onto the substrate while the bias voltage is applied.

In some implementations, the process includes co-sputtering a set of layers of a magnetic material and the crystalline-forming material that forms the two-dimensional material onto the substrate, each subsequent layer after a first layer of the set of layers being co-sputtered onto a previous layer; and altering, for at least one layer, at least one sputtering condition during co-sputtering of the magnetic material and the crystalline-forming material.

In some implementations, the process includes altering at least one sputtering condition during sputtering of the crystalline-forming material onto the substrate.

In some implementations, the at least one sputtering condition comprises a bias voltage value.

In some implementations, the at least one sputtering condition comprises a temperature value of the substrate.

In some implementations, the at least one sputtering condition comprises a volume % of the crystalline-forming material relative to another material being co-sputtered.

In some implementations, the process includes sputtering the crystalline-forming material onto the substrate for a period of time without applying the bias voltage; and after the period of time, applying the bias voltage to the substrate, wherein the crystalline-forming material comprises an amorphous material corresponding to the period of time without applying the bias voltage and the two-dimensional material corresponding to the period of time while applying the bias voltage.

In some implementations, the two-dimensional material comprises a hexagonal boron-nitride (h-BN) structure. In some implementations, the two-dimensional material comprises borophene. In some implementations, the two-dimensional material comprises graphene. In some implementations, the two-dimensional material comprises transition metal dichalcogenides (TMDs).

In an aspect, an integrated circuit includes a plurality of wires; and a filler material among the wires of the plurality of wires, the filler material comprising a two-dimensional material configured to conduct heat away from the wires.

The In some implementations, the IC includes a substrate having an edge, wherein the two-dimensional material comprises one or more crystalline sheets, and wherein the crystalline sheets are oriented to conduct heat away from the wires to the edge of the substrate.

In some embodiments, the described herein may be monolithically integrated with integrated circuits, or as stand-alone high storage capacity memory chips.

The details of one or more embodiments of these systems and methods are set forth in the accompanying drawings and the description below. Other features, objects, and advantages of these systems and methods will be apparent from the description and drawings, and from the claims.

### BRIEF DESCRIPTION OF THE FIGURES

FIG. 1 illustrates 2D material layers formed in the sputtered layers conformally coating lithography-patterned surface structures.

FIG. 2 illustrates 2D materials formed using different deposition temperatures and substrate biases.

FIG. 3 illustrates Raman spectra of 5 nm-thick h-BN films deposited on textured MgO (001), Cr (001), and amorphous Ta (a-Ta) underlayers.

FIG. 4 illustrates plane views using high-resolution transmission electron microscopy (HRTEM) images of the exfoliated h-BN layers.

FIG. 5A illustrates a film stack of FePt-2DM nanogranular films.

FIG. 5B shows an illustration of 2D material among magnetic grains.

FIG. 5C shows a plane, top view image of the 2D material among magnetic grains.

FIG. 5D shows a cross-section view of a thin film including magnetic grains.

FIG. 5E shows a cross-section view of a thin film including magnetic grains.

FIG. 5F shows an illustration of the cross-section view of the thin film of FIG. 5E.

FIG. 6A shows a top view of a microstructure of FePt-(h-BN) thin film produced by the film stack in FIG. 5A.

FIG. 6B illustrates a histogram of approximate grain diameter sizes.

FIG. 6C illustrates a magnetic hysteresis graph.

FIG. 6D illustrates a side view of a thin film.

FIG. 6E illustrates an X-ray diffraction (XRD) pattern of the thin film of FIG. 6D.

FIG. 7 illustrates film stack of FePt-2DM nanogranular films with an altered sputtering temperature condition.

FIG. 8A illustrates a top view of an example FePt-2DM granular thin film produced using the film stack in FIG. 7.

FIG. 8B illustrates a side, cross-section view of an example FePt-2DM granular thin film produced using the film stack in FIG. 7.

FIG. 8C illustrates histogram of approximate grain diameter sizes of a thin film produced using the film stack in FIG. 7.

FIG. 8D illustrates histogram of approximate pitch distances of a thin film produced using the film stack in FIG. 7.

FIG. 8E illustrates a magnetic hysteresis graph produced using the film stack in FIG. 7.

FIG. 9A illustrates a top view high-resolution transmission electron microscopy (HRTEM) image of a FePt-2DM thin film produced using the film stack in FIG. 7.

FIG. 9B illustrates a side view high-resolution transmission electron microscopy (HRTEM) image of a FePt-2DM thin film produced using the film stack in FIG. 7.

FIG. 10 illustrates cross-sectional views of a multilayer nanofilm sample of [h-BN/FePt]×13 utilized to measure the thermal conductivities in the materials system.

FIGS. 11A, 11B, and 11C each illustrates a graph of three-omega measurement results of the sample of FIG. 10.

FIG. 12 illustrates an example process, according to some implementations.

FIG. 13 illustrates an example process, according to some implementations.

FIGS. 14A, 14B, 14C, and 14D show examples of a 2DM for use as a filler in an integrated circuit.

### DETAILED DESCRIPTION

This disclosure describes a process to form 2D materials (2DMs) with a bottom-up method of depositing single-layer or multilayer 2D crystalline materials through bias sputtering at high temperatures. The 2D crystalline materials can include materials such as hexagonal boron nitride (h-BN), borophene, graphene, transition metal dichalcogenides (TMDs) and so forth. This disclosure further describes various composite thin films comprising 2D materials and other materials and the processes for formation of the thin films. The deposition method can be based on sputter deposition, enabling a highly scalable and economic process to form the 2D materials.

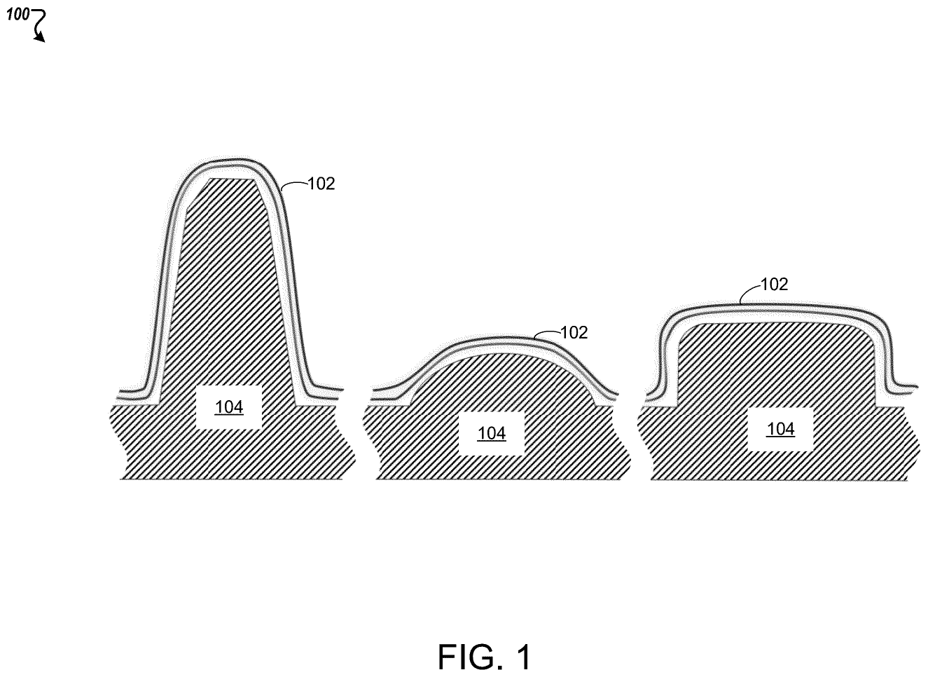

FIG. 1 shows examples 100 of deposition of 2DMs 102 on structures 104. The deposition method of the 2DMs is scalable. Multilayer or single layer of crystalline materials can be grown on an underlayer or substrate via the sputtering technique with moderate substrate bias (e.g. from −5V to −20V), applied by either radio frequency (RF) or direct current (DC) sources at adequately high substrate temperature (e.g. from 300° C. to 850° C.) during material deposition. The moderate substrate bias voltage facilitates formation of the crystalline 2D materials and eliminates or minimizes the amorphous phases of the crystalline 2D materials. The first few layers of 2D materials 102 formed through this method conform to the underlayer surfaces 104, enabling conformal coating of 2D materials on lithography-patterned structures for device applications.

The processes described herein enable formation of columnar magnetic grains having large aspect ratios. In an example, the process includes deposition of a granular nanocomposite thin film of L1₀-ordered iron-platinum (FePt) grains with 2DMs as the grain boundary materials to produce well-separated, tall and columnar FePt grains. This composite nanogranular thin film can be used as a recording media for heat-assisted magnetic recording (HAMR) technology. The boundary material is thermally insulating and non-magnetic.

The process for depositing 2D materials onto substrates can include a sputtering technique. By applying a moderate substrate bias voltage and maintaining adequately high substrate temperatures during deposition (as subsequently described in further detail), crystalline 2D materials are formed with minimized components of amorphous phases. This deposition method is versatile for producing various composite thin films comprising 2D materials and other materials.

The 2DMs can form a recording material as follows. In an aspect, an ultrathin layer of magnetic material (such as iron (Fe)) is sputtered onto a substrate as a nucleation (seed) layer. The iron layer can define nucleation sites for following grain growth. Next, a layer of amorphous grain-boundary material (e.g., BN) is sputtered onto the nucleation layer. A magnetic material, such as iron-platinum, is sputtered onto the nucleation layer either separated from the amorphous boundary material or in combination with the amorphous boundary material. In some implementations, the amorphous layer is co-sputtered with the magnetic material. For example, the magnetic material (e.g., Fe—Pt) can be co-deposited with the boundary material (e.g., BN). The magnetic material grows columnar grains seeded by the nuclei embedded in the amorphous grain boundary material. Because the deposition occurs without a substrate bias (as described herein) the grain boundary material remains amorphous and forms the boundaries around the grains as the crystalline grains expand.

The crystalline grains of the magnetic material expand in crystalline direction (facets). The crystalline grains grow in height (to satisfy a volume requirement for use as memory bits) and in diameter based on the facet angle. When a desired diameter of the grains is reached, a bias voltage is applied to the substrate. The substrate bias voltage causes the deposited grain boundary material to form crystalline planes. The crystalline planes (e.g., honeycomb sheets) of the grain boundary material are approximately perpendicular to the substrate, as described herein, and form around the magnetic grains. The crystalline layers of the grain boundary material cause the magnetic grains to grow vertically away from the substrate without further expansion of their diameters. This is because the crystalline layers of the boundary material are relatively immovable. The boundary material, when amorphous (e.g., when no substrate bias is applied), is movable (e.g., squeezable) by the growth of the magnetic grains (e.g., Fe—Pt grains). The diameter of the grains can be precisely tuned by applying the bias voltage to the boundary material to form the rigid, vertical crystallin planes of the grain boundary material around the metallic grains precisely when the desired grain diameter is achieved, causing approximately vertical grain boundaries. The resulting material has high separation between the grains and strong thermal insulation and magnetic insulation between the grains.

The two-dimensional materials can be formed by sputtering onto a substrate. For example, for thin film recording media applications, the two-dimensional materials can be co-sputtered onto a substrate with the magnetic material (e.g., FePt) configured for forming the magnetic grains of the recording medium. In another example, the two-dimensional materials can be sputtered onto structures, like wires or trenches, on a substrate formed from lithographic or other patterning processes. The two-dimensional material can form a filler material configured to conduct heat away from the patterned structures along the crystalline sheets of the two-dimensional material. For example, the filler material can be part of an integrated circuit (IC), and the two-dimensional material can conduct heat to an edge of the IC or to a heat sink of the IC for thermal management of the IC. In another example, the two-dimensional material is formed on a substrate by sputtering under a bias voltage without another material present.

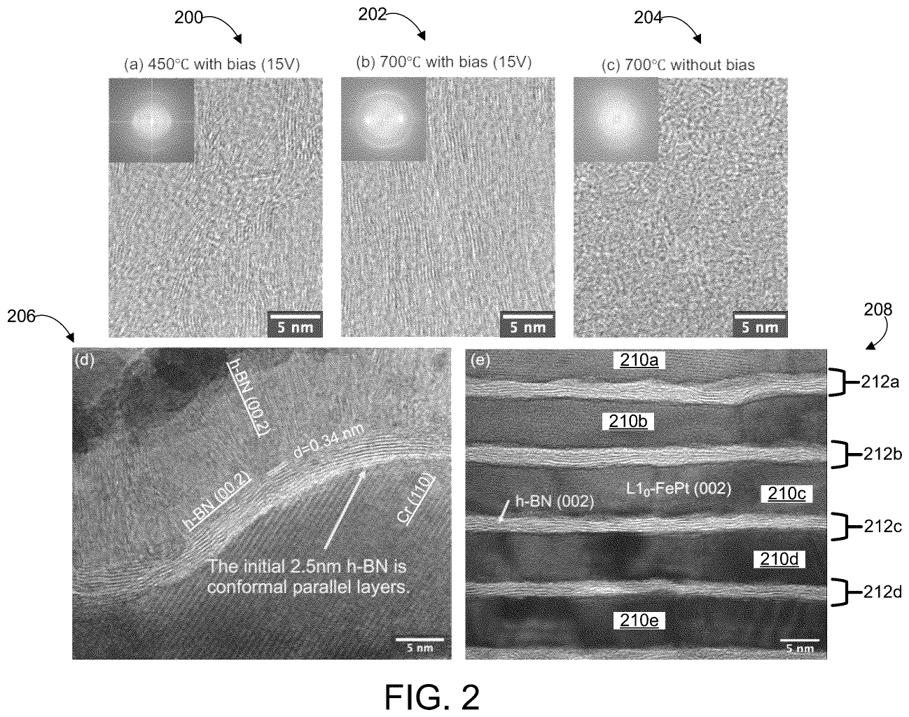

FIG. 2 shows, using h-BN as an example, three experimental results images 200, 202, 204 demonstrating the effect of high substrate temperature and substrate bias voltage on the quality of pure BN blanket layers sputtered on FePt surfaces. The control sample 202 in the middle was deposited at 700° C. with a substrate bias voltage of −15V (generated by an RF power of 3 watts (W)) to yield the h-BN phase, as verified by its fast Fourier transform (FFT) pattern. In comparison, when removing the bias voltage, as shown in example result image 204, the resulting BN film was completely amorphous. Alternatively, when the temperature was lowered to 450° C. while the bias was maintained, layered structures were observed result image 200, but they were poorly crystallized. These three result images 200, 202, 204 reveal that substrate bias is a critical condition for the formation of crystalline h-BN, while high temperature improves the crystallinity of the film.

Experimental result image 206 shows an HRTEM cross-sectional image of the h-BN blanket layer deposited using the novel deposition method on a curved Cr underlayer. Image 206 shows that h-BN adopts a layer-by-layer growth conforming to the metal surfaces, regardless of the surface curvatures, in the initial ˜2.5 nm layers (about 6-8 h-BN nanosheets). Image 208 shows sets of 2DM layers 212a-d, each comprising multiple crystalline sheets, between magnetic material layers 210a-d parallel to the substrate plane.

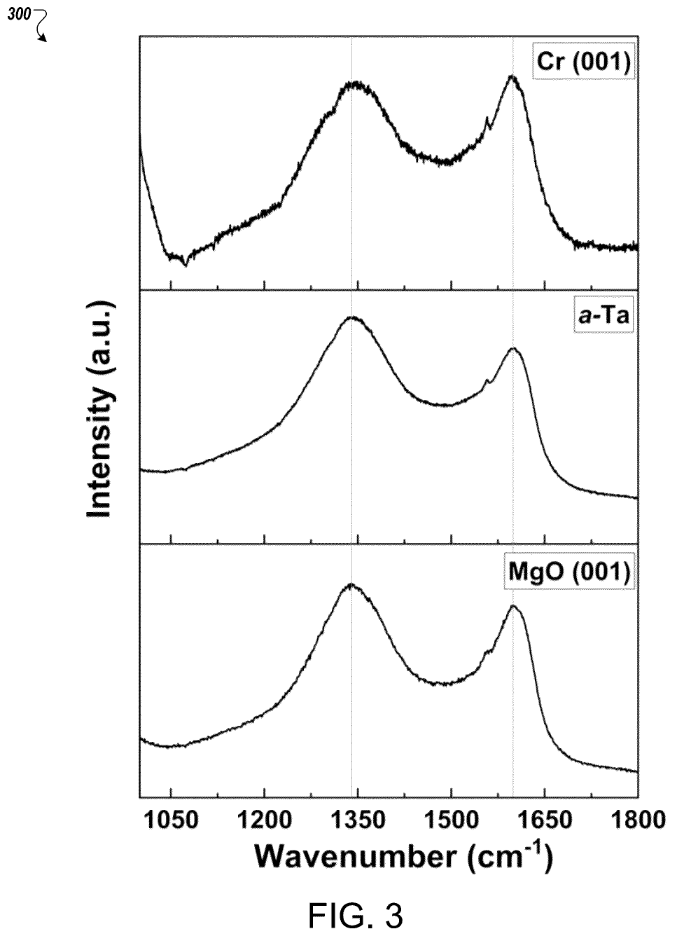

FIG. 3 illustrates a graph 300 showing Raman spectra for h-BN deposited on Cr (001), MgO (001), and amorphous Tantalum (a-Ta) layers via the bias-sputtering method with appropriate substrate bias and substrate temperature. The h-BN layer is 15 nm thick and it is capped by a 3 nm layer of amorphous carbon (a-C). For all data the excitation wavelength was λ=532 nm. In the Raman spectrum, the small shoulder on the left of the peak centered at wavenumber k=1340 cm⁻¹ for the Cr (001) and a-Ta underlayers indicates two overlapping peaks. These peaks can be indexed to the D and E_{2G} peaks of a-C and h-BN, respectively. The peak near 1600 cm⁻¹ represents the G peak associated with a-C. The Raman data 300 show that this novel bias-sputtering method is not restricted to an underlayer or substrate with lattice matching, enabling growth of 2D materials on various substrate including amorphous/crystalline metals or ceramics.

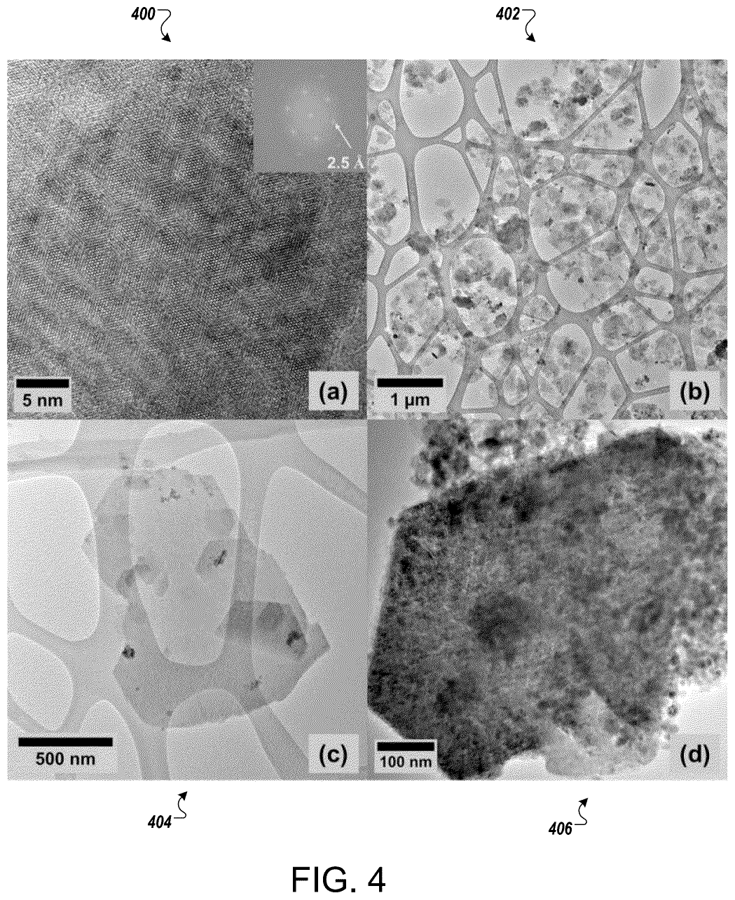

FIG. 4 shows images 400, 402, 404, and 406 of the thin film material. The 2-nm-thick multilayers of h-BN deposited on MgO (001) or Cr (001) using appropriate substrate bias and substrate temperature can be exfoliated for plane-view HRTEM imaging. As shown in image 400, the 2D hexagonal lattice structure exhibits a lattice spacing of 2.5 Angstroms (Å), corresponding to the lattice constant a of h-BN. Notably, the Moiré fringes associated with a 2° twist between two overlapped hexagonal lattice structures are also observed. Image 402 shows roughly the expected grain size of h-BN platelets deposited onto MgO (001) which are on the scale of 0.5-1 micrometers (μm). By tuning the target and substrate bias voltages and temperature conditions, large area single crystalline h-BN of sizes on the order of 10⁰-10⁴ μm can be achieved. Images 404, 406 show that the sputtering process previously described can achieve h-BN flakes with hexagonal facets, a behavior associated with the concentration of deposited atoms at the substrate surface. To achieve hexagonal facets, equiatomic B and N are used, which contrasts to the CVD-deposited triangular h-BN flakes where an excess of B or N atoms can be introduced during CVD growth process.

Based on the bias-sputtering technique for deposition of 2D materials, a wafer-scale composite multilayer thin film can be fabricated. The multilayer thin film comprises of an alternating stack of sub-10 nm thick layers of 2D materials and other materials, which can form a superlattice structure with sharp, flat and smooth interfaces. The few-layer 2D materials deposited through bias sputtering at high temperature can develop a (002) texture. This indicates that the monolayers of the 2DMs are parallel to the interface with other materials like transition metals.

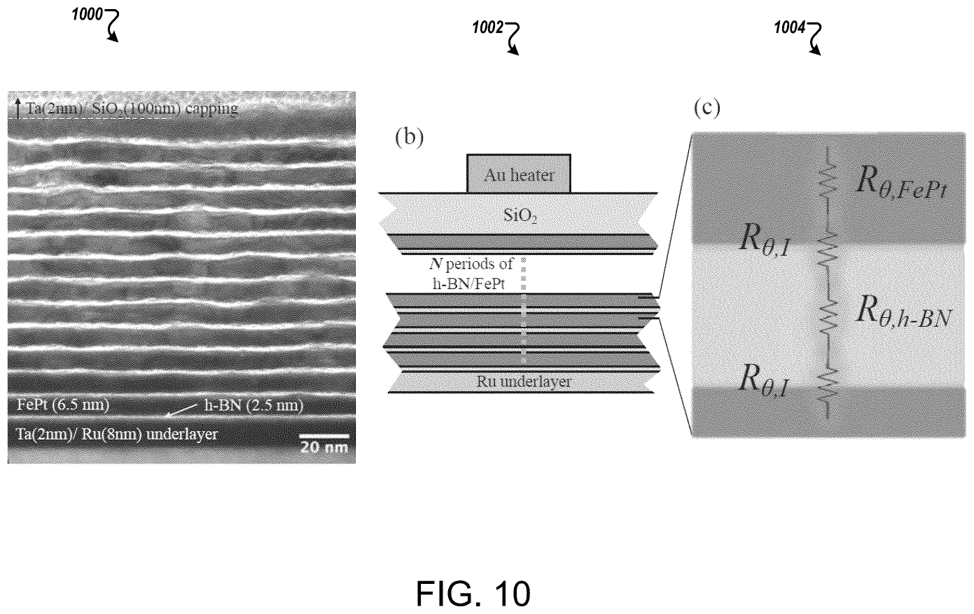

An example of the multilayer nanofilms includes the [h-BN/FePt]×N film where N is the number of periods, as shown in images 208 of FIG. 2 and image 1000 of FIG. 10, subsequently described. Each few-layer h-BN layer of 2.5 nm is deposited at 700° C. with a substrate bias voltage over the range of −5 to −10V, generated by a RF power of 3 W applied on the substrate. Each FePt layer is DC-sputtered at relative low temperatures (e.g., less than 100° C.). Image 208 of FIG. 2, an HRTEM cross-sectional image, exhibits the superlattice nanostructure of this multilayer film. In this example, the BN layers form crystalline h-BN nanosheets with monolayers parallel to the interface with FePt, (e.g., all have developed the (002) texture). The superlattice nanostructure with van der Waals interfaces render ultra-low thermal conductivities to the [h-BN/FePt]×N multilayer films, as shown in image 200 of FIG. 2.

As indicated previously, the bias-sputtering technique of crystalline 2D materials can be employed to deposit nanocomposite thin films incorporating 2D materials and other materials through co-sputtering. For example, a graded deposition process for FePt-2DM nanogranular thin films can be applied with varying sputter conditions. Varying the sputtering conditions such as temperature, bias voltage, or volume % of the co-sputtered materials can optimize the microstructure of the FePt-2DM films.

An example of the film fabricated using the graded deposition process includes FePt-(h-BN) granular thin films. These thin films can be utilized in high density recording media. The effective parameter-varying processes that have been validated include a decreasing h-BN volume fraction from bottom to top (adjusted by varying the RF power of BN target), coupled with moderate substrate bias voltages (typically −5V to −20V) and appropriately decreasing the elevated substrate temperatures during the deposition. This method can be extended to other 2D materials such as graphene, transition metal dichalcogenides (TMDs) and so on. Compared to the amorphous grain boundary materials, like carbon and SiO₂, the 2D nanosheets generated using the described process include a higher thermal stability and strength, due to their strong covalent bonds within the monolayers. The introduction of the 2D grain boundary materials effectively develop the columnar growth of FePt by inhibiting the lateral growth or coalescence between adjacent grains in the as-deposited film at substrate temperatures up to about 850° C.

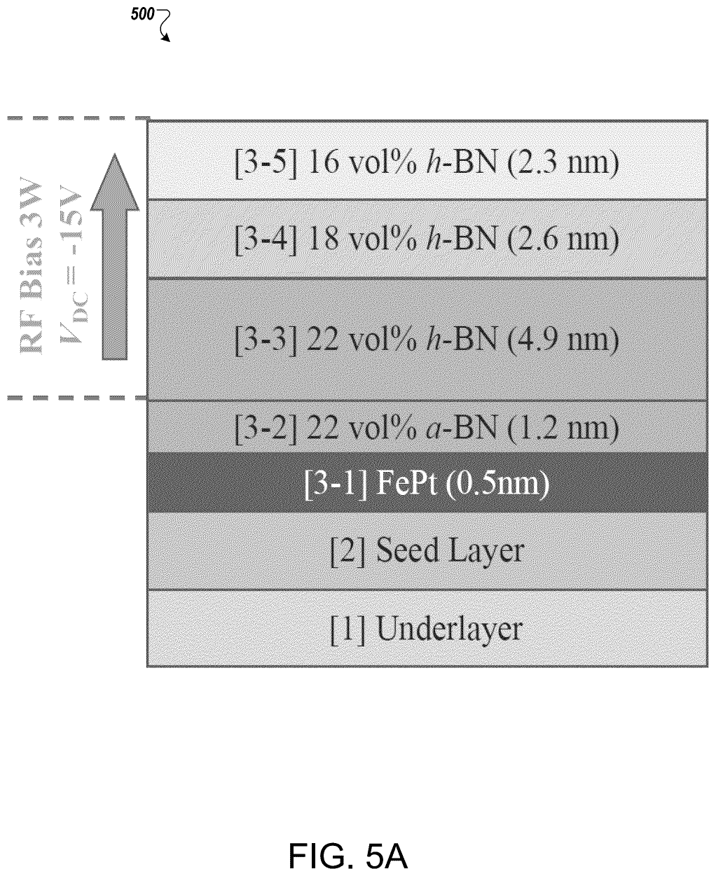

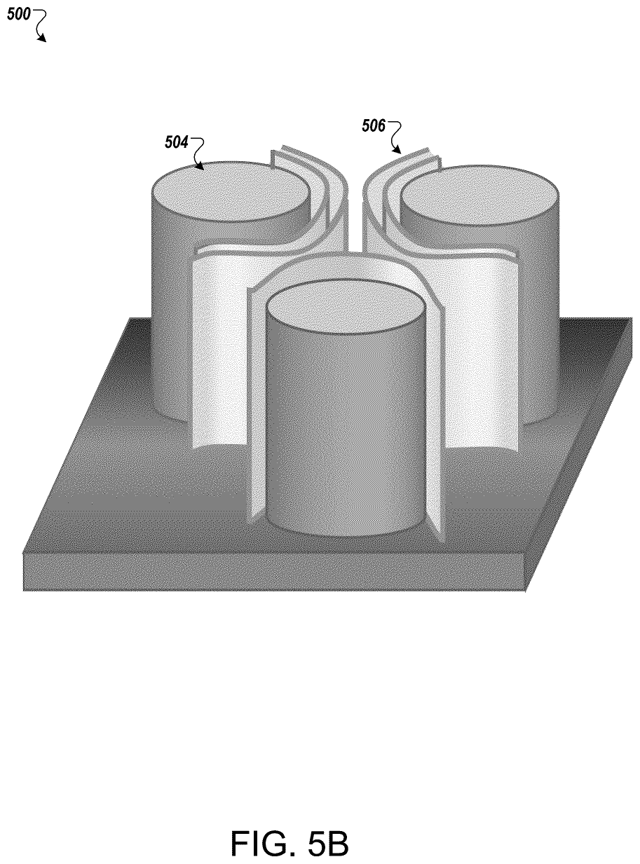

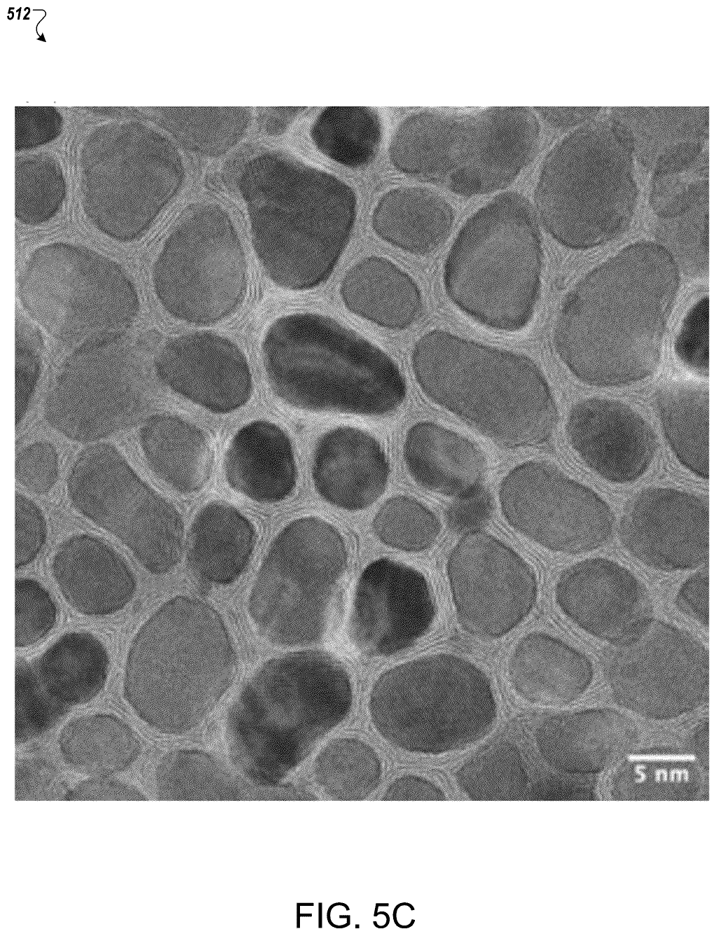

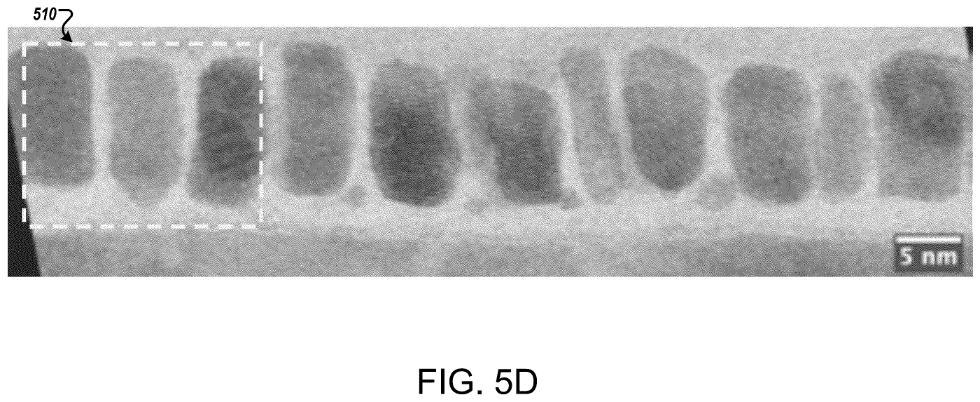

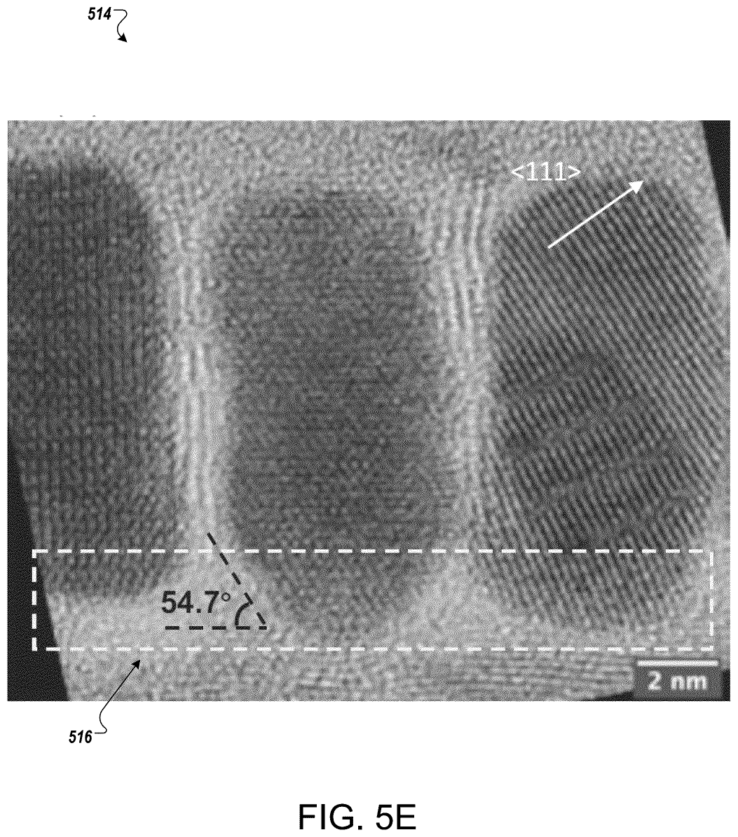

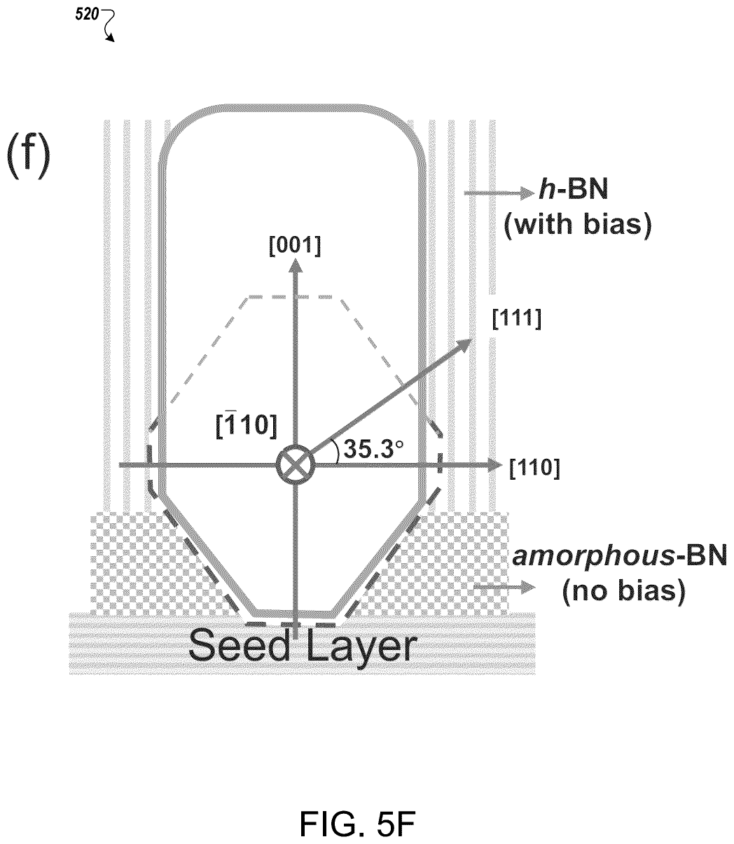

FIG. 5A shows an example film stack as an example of the implementation of the graded deposition process. The film stack 500 includes an [1] Underlayer and [2] Seed Layer to serve as the heat sink and to develop strong (001) texture and perpendicular L1₀ ordering of the FePt thin films grown on these layers. Once the substrates [1] and [2] are obtained, the FePt-2DM recording layer is deposited at high temperatures in a stepwise manner with graded sputter conditions. The graded film stack comprises nearly equiatomic FePt alloy co-sputtered with some 2D grain boundary materials under different sputtering conditions that are gradually altered from bottom to top. Bottom layer [3-1] includes a thin layer of pure (or nearly pure) FePt used to improve the nucleation stage which can contribute to a more uniform grain distribution overall. From the bottom layer [3-1] to a top layer [3-5], an elevated substrate temperature (e.g., 300° C.-850° C.) is maintained constant while the volume fractions of grain boundary materials are decremented to facilitate the consistent columnar growth of FePt grains. In an example, the volume fractions of the grain boundary materials is reduced by decrementing the RF sputter power on BN targets. In some implementations, when deposited with a fixed concentration of h-BN, some FePt grains can be capped with the excessive BN. Reducing the volume percentage can prevent undesired formation of a second-layer FePt grains. A substrate bias voltage, generated by either a DC or an RF power source, is applied from layer [3-3] to layer [3-5] to facilitate the crystallization of 2D materials nanosheets. For example, for h-BN, which forms amorphous phases if deposited without substrate bias, the bias voltage facilitates the crystallization of 2D materials nanosheets. The substrate bias can also be delayed for tuning the resulting granular microstructure, as previously described. For example, layer [3-2] that is deposited without the substrate bias is inserted in the film stack. After the layer [3-2] is deposited, the voltage bias is applied to the substrate.

FIG. 5B illustrates an example perspective view of the thin film 502. Sheets 506 of the 2DM material conform or surround the grains 504. The grains 504 are nearly vertical. FIG. 5C shows a plane view TEM image 512 of the thin film from stack 500. FIG. 5D shows a side-view TEM image 508 of the FePt-(h-BN) film deposited using the novel method and the film stack 500. The plane-view image 512 of FIG. 5C indicates that FePt grains are well separated by the h-BN nanosheets that conform to grains' side-surfaces and encircle each grain. The cross-section view image 508 of FIG. 5D shows that FePt forms columnar grains (e.g., in box 510) with average lateral diameter <D>=6.65 nm, average height <h>=11 nm, therefore grain aspect ratio (h/D)=1.65. The h-BN nanosheets in the grain boundaries serve as a stable barrier to stop lateral coalescence and lateral growth of FePt grains.

FIG. 5E shows a bright-field scanning transmission electron micrograph (BF-STEM) cross-sectional image 514. The image 514 shows a detailed nanostructure near an interface between FePt grains and BN grain boundaries. In layer [3-2] of stack 500, grown prior to the application of substrate bias and shown in box 516, the BN materials in grain boundaries appear amorphous, and the FePt grains are shown to grow in both lateral and perpendicular directions with specific crystalline facets that match the equilibrium shape (Wulff construction) of L1₀ FePt nanocrystal. The illustration 520 in FIG. 5F shows the view of the Wulff polyhedron along [110] direction (dashed line) matching the bottom of FePt grain in the cross-section view image in the box 516 of FIG. 5E. The high deposition temperature causes the facet forming of FePt nanocrystals (e.g., at angles shown in the images, which are based on the type of 2DM used). After applying substrate bias in layer [3-3], h-BN nanosheets start forming in the grain boundaries, with the flexible monolayers growing parallel to the side surfaces of FePt grains. The initiation of perpendicular h-BN nanosheet formation aligns well with the start of columnar growth of the FePt grains. The h-BN effectively inhibits the lateral growth of the FePt grains, as the h-BN monolayers grow continuously in the boundary regions, keeping up with the growth of FePt grains.

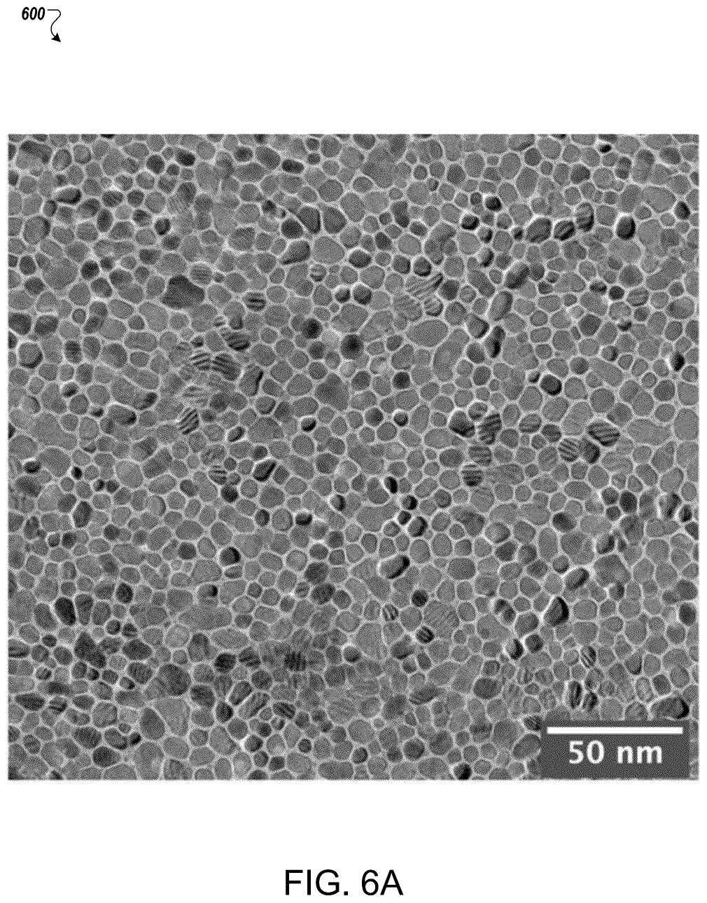

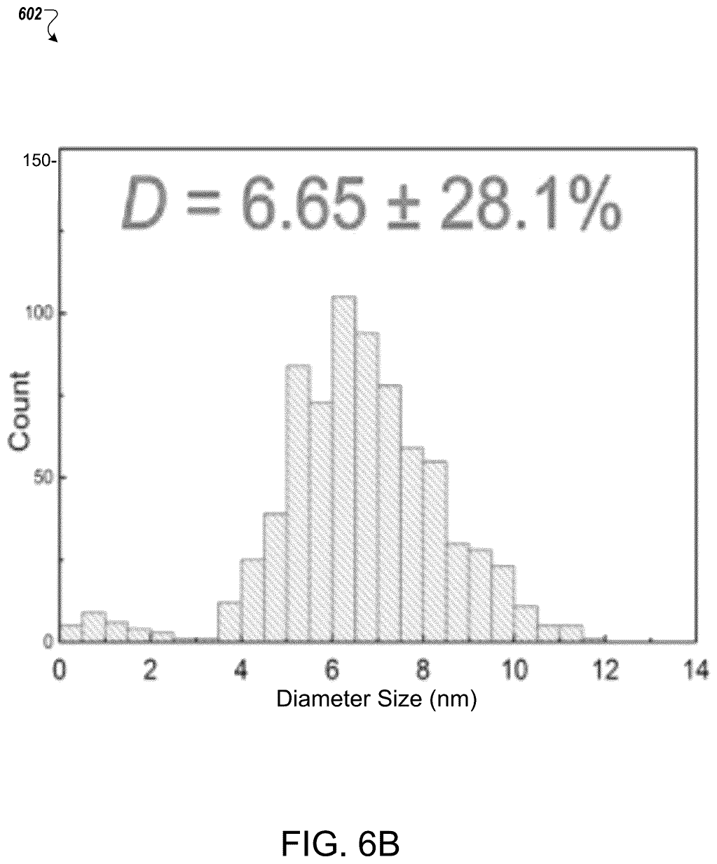

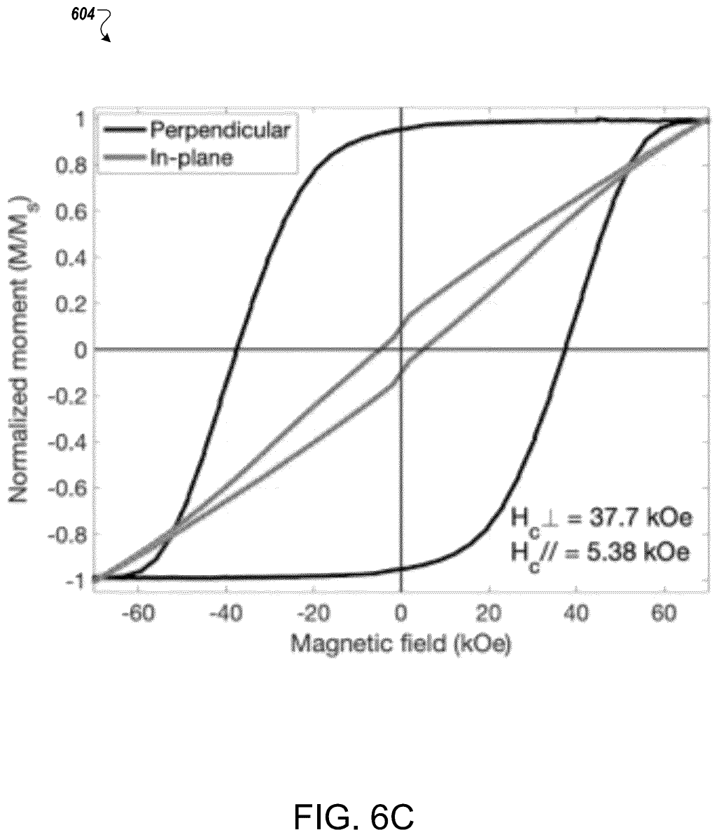

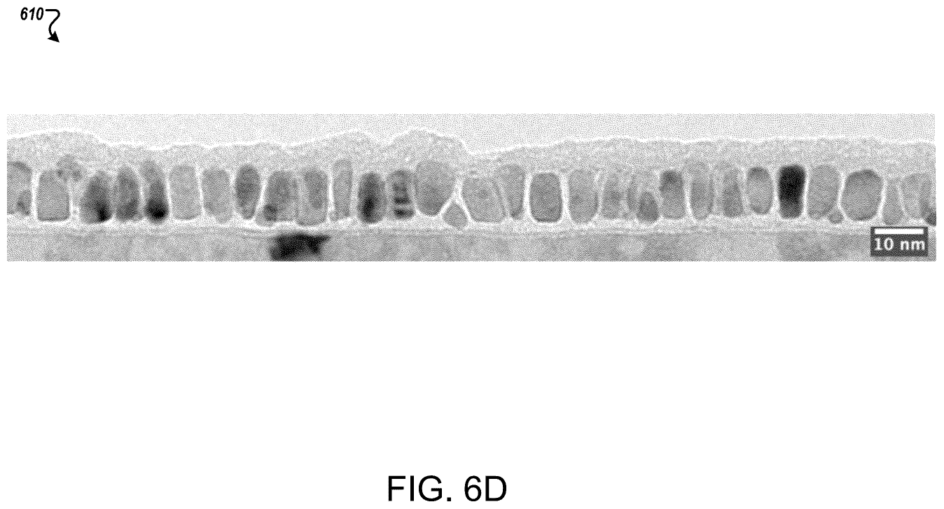

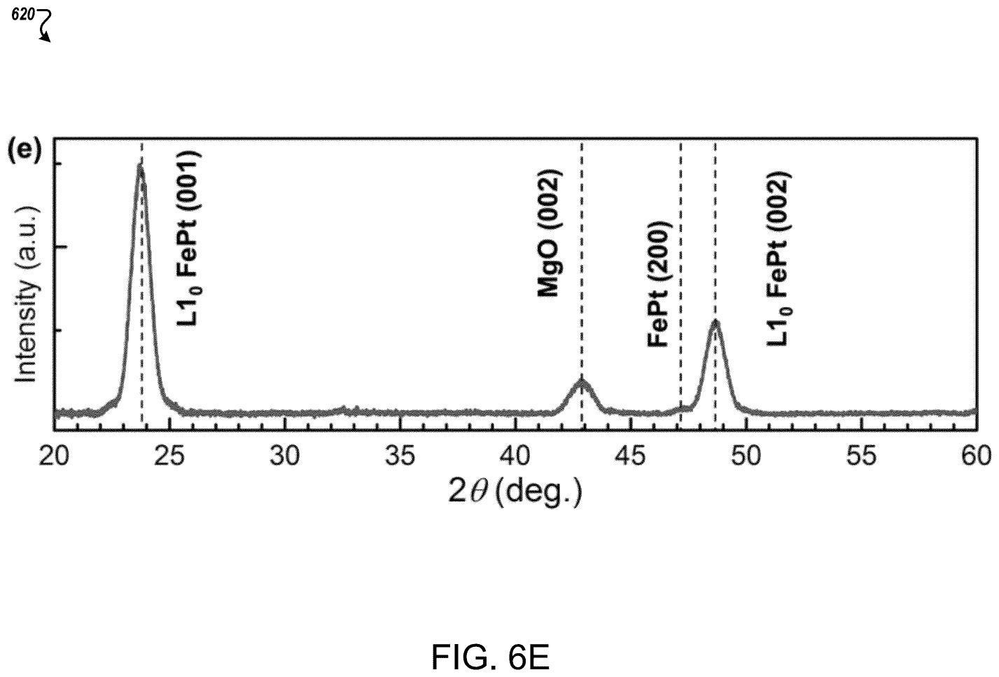

FIG. 6A shows a plane-view TEM image 600 over a larger area of the sample shown in FIG. 5C. Well-defined granular microstructure indicates that most FePt grains are completely encircled by the BN grain boundaries. A grain size distribution analysis indicates that the grain size is 6.65±1.87 nm, and the grain center-to-center pitch distance is 8.24±1.93 nm. Graph 602 of FIG. 6B shows diameter sizes, and graph 604 of FIG. 6C shows a magnetic hysteresis analysis. Specifically, graph 604 shows perpendicular and in-plane magnetic hysteresis loops, measured at room temperature, with a perpendicular coercivity of 37.7 kilo-oersted (kOe) and an in-plane coercivity of 5.38 kOe. FIG. 6D illustrates a typical cross-sectional TEM image 610 of the thin film sample (e.g., from FIG. 6A) showing that most grains are columnar.

FIG. 6E illustrates a graph 620 of an out-of-plane X-ray diffraction (ORD) pattern. No (111) peaks are observed, indicating good (001) texture for FePt grains. The integrated intensity ratio of the L1₀-ordered superlattice peak (001) to the fundamental peak (002) (I₀₀₁/I₀₀₂) is about 2.53, and the order parameter is S=0.78. These parameter values indicate that the 11-nm-tall FePt-(h-BN) film deposited using the described method is well-suited for the HAMR media application.

The formation of h-BN grain boundaries can enable good granular microstructures and high out-of-plane magnetic coercivities in the FePt-(h-BN) granular film, because the high ordering of L1₀ FePt phase can require relatively high substrate temperatures (such as over 600° C.). However, after forming columnar FePt grains with large aspect ratio (>1.6) assisted by envelopment of the h-BN nanosheets grown perpendicular to film planes, the long-time heating (e.g. >10 minutes) will break one columnar FePt grains into small ones. The FePt grains with high aspect ratios (>1.6) still tend to lower the free energy by splitting into smaller spherical grains. Therefore, if the deposition rate is too low and consequently the deposition time at high temperature is too long, the deposited film exhibits a messy microstructure with a lot of broken FePt grains instead of a single layer of columnar grains. To address this problem and enable thicker FePt-2DM films deposition with the graded deposition process, an additional decreasing temperature program can be employed to control the total thermal budget for the FePt-2DM granular films.

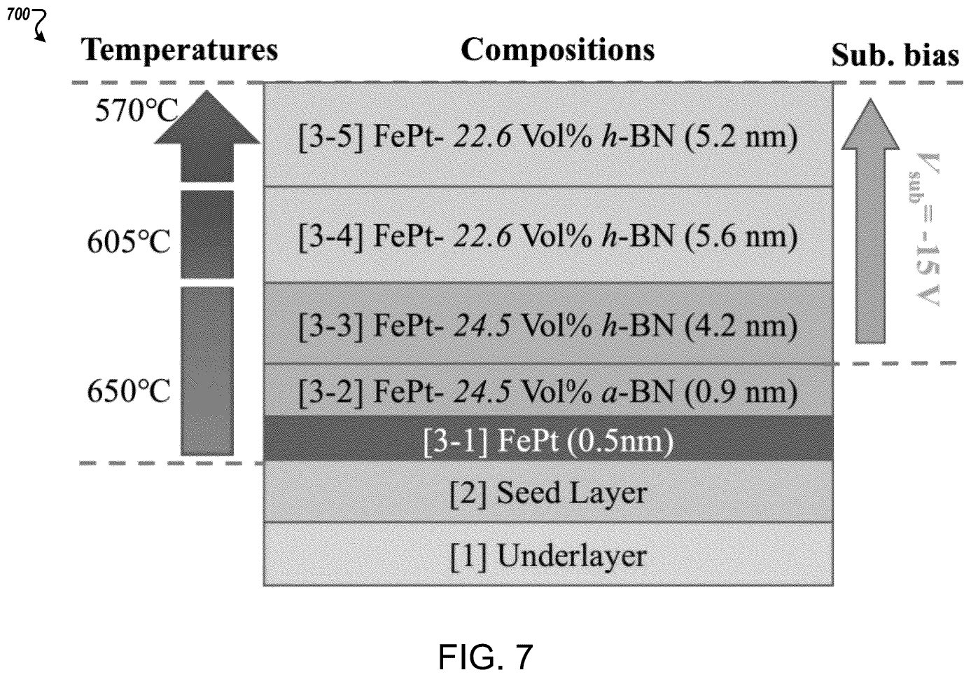

FIG. 7 illustrates the media film stack 700 designed using the extended version of the graded deposition process. The stepwise process for stack 700 combines decreasingly graded substrate temperatures with the substrate bias and decremented h-BN volume fraction from bottom to top. Similar to the material of example 200 of FIG. 2, the FePt-2DM layers from [3-1] to [3-5] are deposited on layer [1] underlayer and [2] seed layers. The sputter conditions or parameters are adjusted as follows. First, a constant substrate bias was applied from layer [3-3] to induce the crystallization of h-BN in the FePt grain boundaries. Second, layers [3-4] and [3-5] have a slightly lower h-BN volume fraction than that of layer [3-3] beneath them. Third, the substrate temperatures are appropriately reduced from bottom to top. To reiterate, the BN volume fraction is decreased to prevent h-BN covering the top of FePt grain, avoiding forming second-layer grains, while grading down the substrate temperature is for preventing the existed columnar FePt grains from breaking into smaller spherical grains.

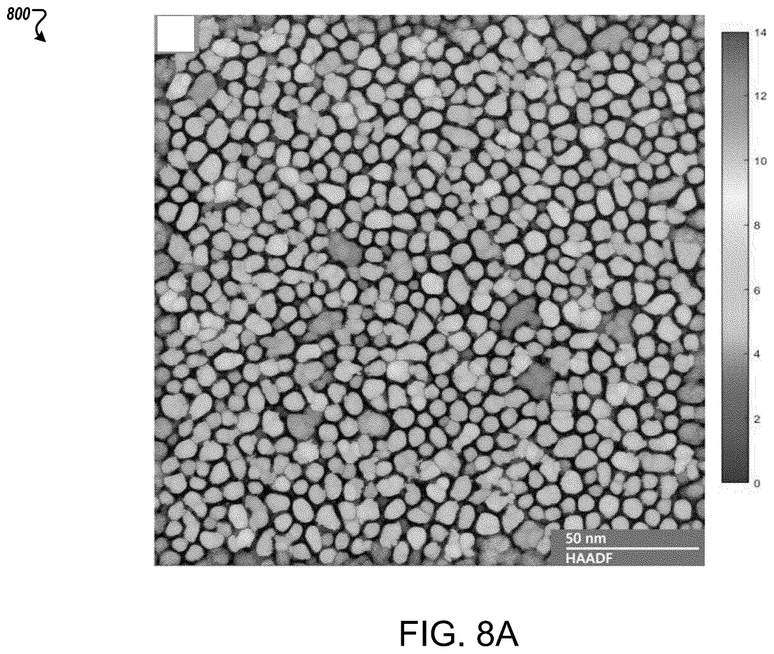

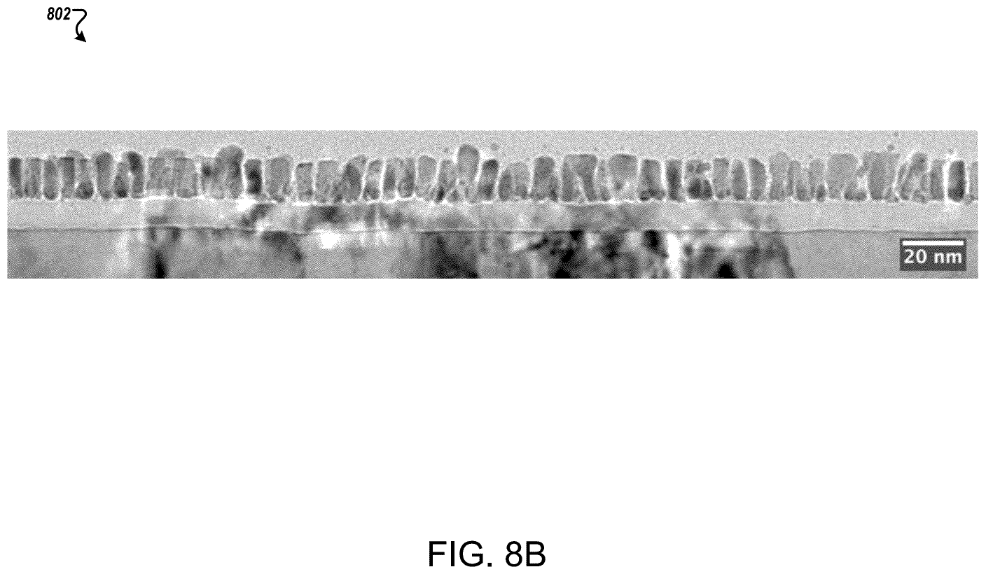

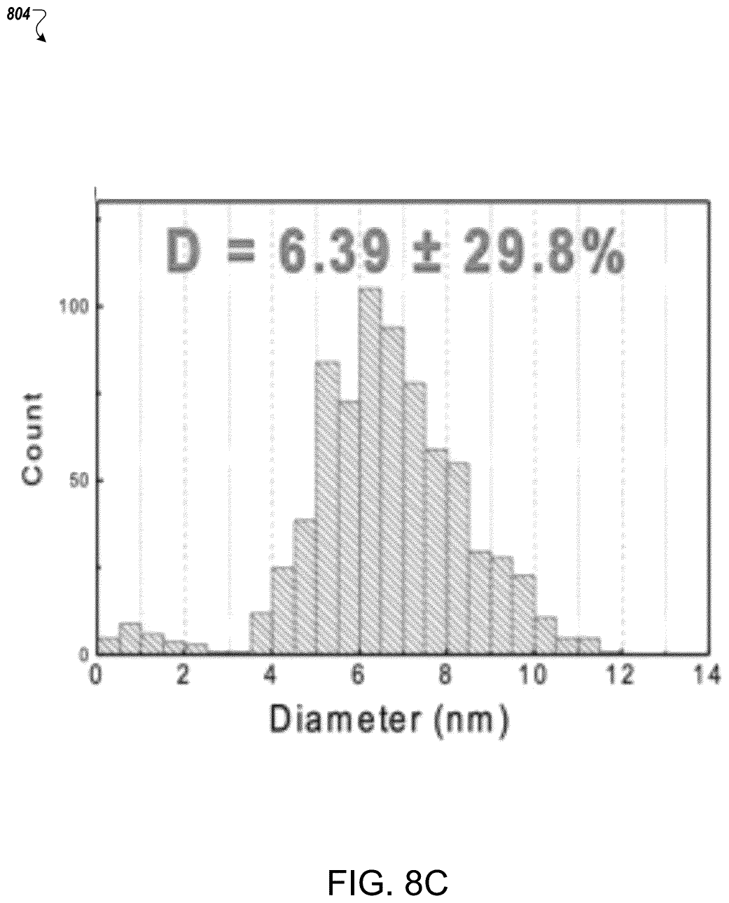

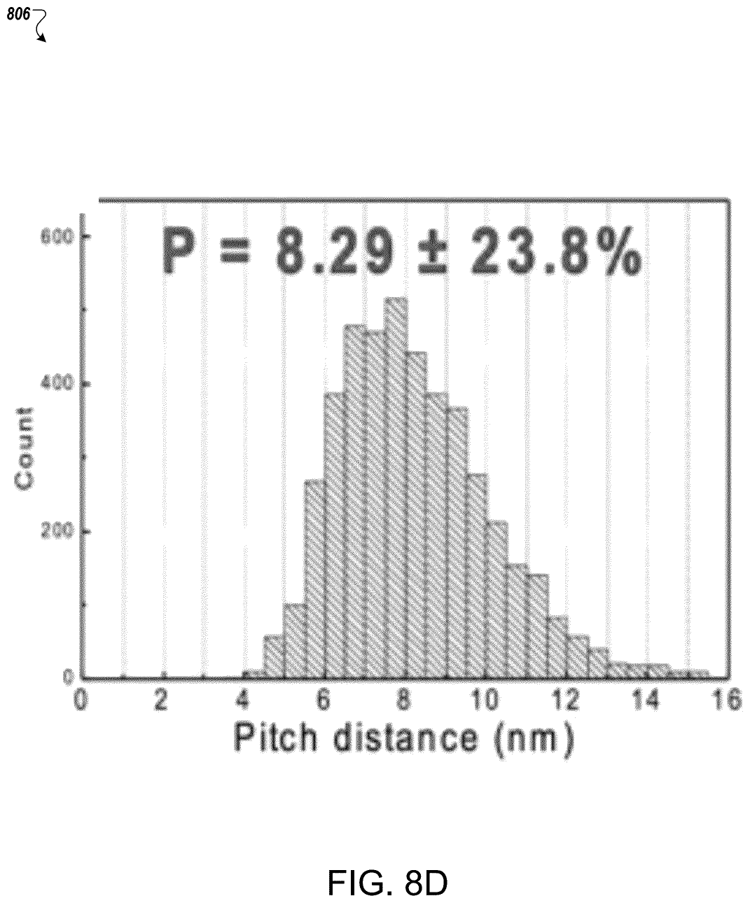

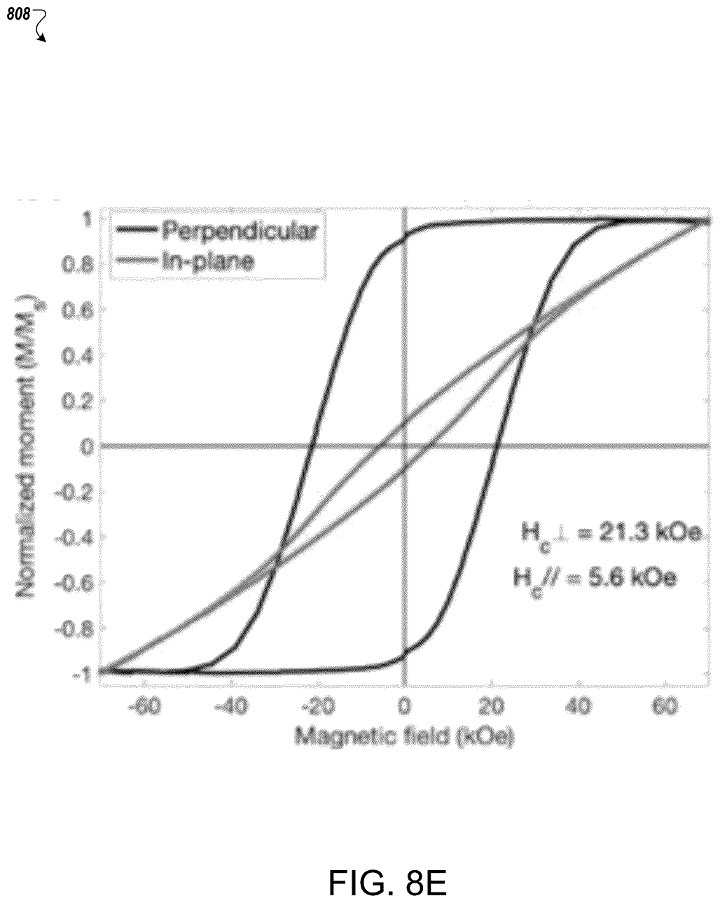

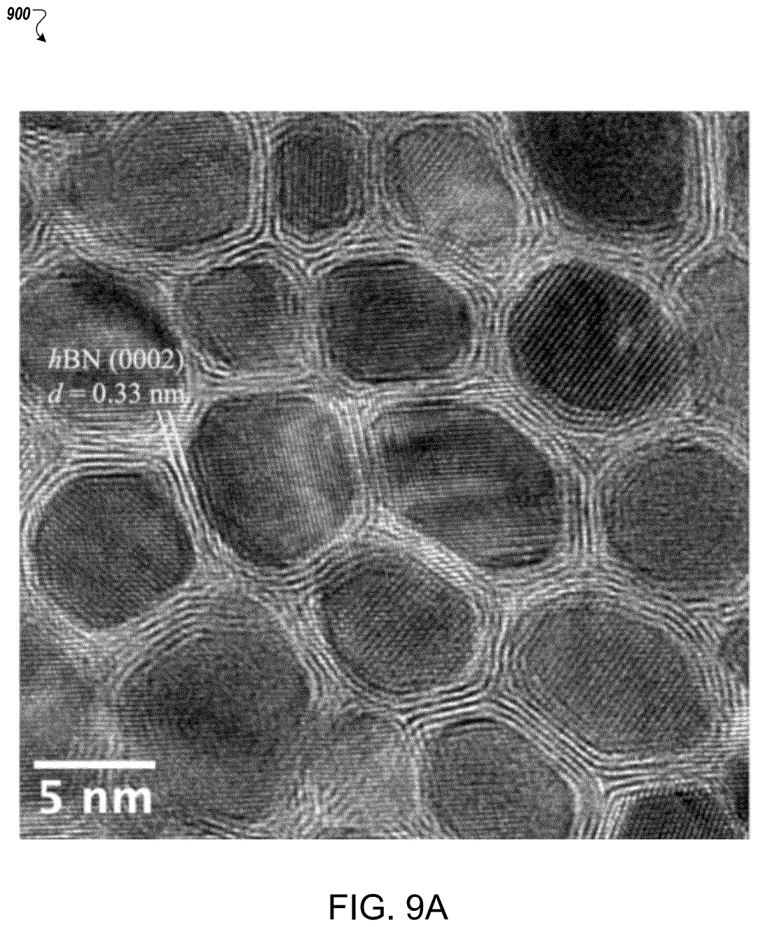

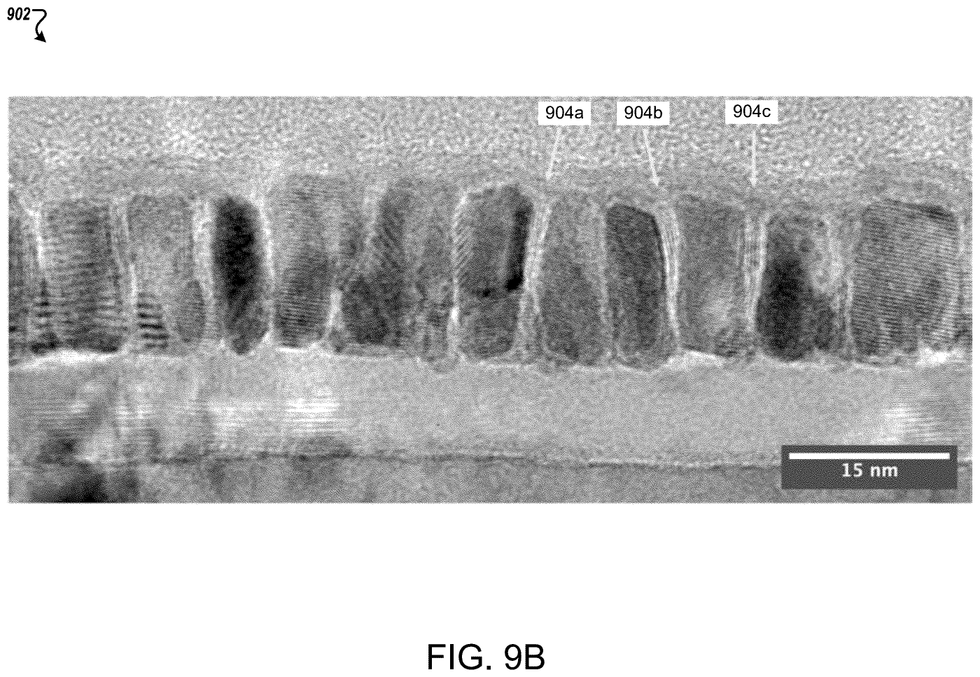

Using the film stack 700 of FIG. 7, the microstructures of the resulting FePt-(h-BN) granular thin films are shown in FIGS. 8A-8E and FIGS. 9A-9B. FIG. 8A illustrates a plane-view STEM image 800 of the film from stack 700. Image 800 reveals small and well-isolated FePt grains with a single peak size distribution, D=6.39±1.91 nm. The center-to-center pitch distance is 8.3±1.9 nm, and the grain areal density is roughly 1.969×10⁴ μm⁻², or 2.7 T/inch². The cross-section TEM image 802 of the same film, illustrated in in FIG. 8B, exhibits a single layer of slender columnar grains. The average film thickness is 16.0 nm, giving rise to a record high FePt grain aspect ratio h/D=2.5. FIG. 8C shows a graph 804 indicating a histogram of diameter sizes of the film of stack 700. FIG. 8D shows a graph 806 indicating a pitch distance of grains of the film of stack 700. FIG. 8E shows a graph 808 indicating magnetic hysteresis of the stack 700.

FIG. 9A shows a magnified plane-view HRTEM image 900 of a thin film from stack 700. FIG. 9B shows a cross-sectional view HRTEM image 902 of the film from stack 700, indicating more clearly that the few-layer h-BN nanosheets in the grain boundaries (e.g., 904a-c) wrap around individual FePt grains with the monolayers conforming to the side grain surfaces. This microstructure clearly illustrates the effect of this novel graded deposition method of columnar FePt grains in FePt-2DM granular thin films. Introducing the decreasingly graded substrate temperature can affect a chemical ordering of L1₀ FePt. The magnetic hysteresis loop shown in graph 808 of FIG. 8E displays an out-of-plane magnetic coercivity of 21.3 kore. Overall, the 16-nm-thick FePt-(h-BN) thin film is useful for magnetic recording applications, given its microstructure and magnetic properties.

A heat-assisted magnetic recording (HAMR) media application is possible with the stacks described herein (e.g., stack 500, stack 700, etc.). The thermal properties of FePt-2DM materials, including the thermal capacitance and thermal conductivity of FePt, 2D material grain boundaries and their interfaces are useful for recording media. The in-plane temperature gradient can control jitter noise and design of overcoat and heatsink layers. The artificial multilayer [FePt/h-BN]×N thin film can be a simplified model to measure those fundamental thermal properties.

FIG. 10 shows an example multilayer 1000 of [FePt/h-BN(002)]×N with smooth and clear-cut interfaces can be deposited through sequential sputtering of FePt(6.5 nm) at room temperature and h-BN (2.5 nm) at 700° C. The h-BN layers (e.g., shown in image 1002) are deposited using the bias sputtering method with a substrate bias voltage over the range of −5 to −10V, generated by a RF power of 3 Watts applied on the substrate. The effective thermal resistance of this superlattice structure scales with the number of FePt/h-BN periods (N) linearly. The slope of the effective thermal resistance as a function of N is (R_{FePt}+R_{h-BN}+2Rᵢₙₜₑᵣ) since the building block is h-BN/FePt bilayer as illustrated in by layers 1004.

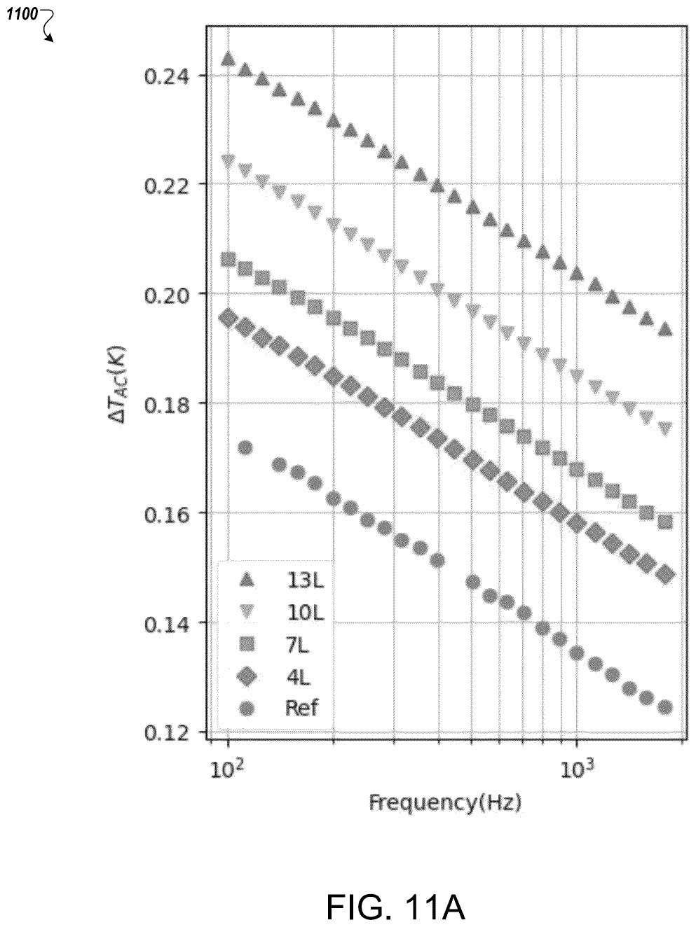

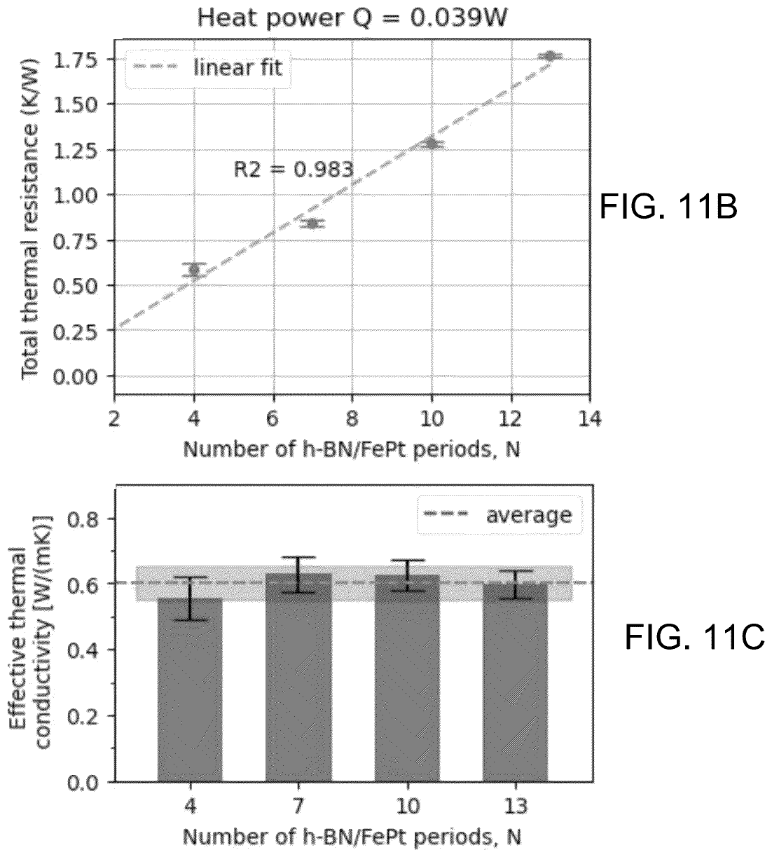

FIGS. 11A-C illustrate the three-omega measurement results from the setup described in relation to FIG. 10. FIG. 11A illustrates a graph 1100 that indicates an average amplitude of two-omega temperature oscillation (ΔT_{h,2f}) of the gold resistive heater at frequency 2f_{drive}, driven by the driving alternating current (AC) of frequency 1f_{drive}. All lines are parallel to the reference sample, showing that the measurement results are reliable and consistent. From the offsets between those parallel lines with the reference line, we can calculate the effective thermal resistance and thermal conductivity of the [FePt/h-BN]×N multilayer stack. Graph 1100 shows an ultralow effective thermal conductivity of 0.6±0.05 Watts per meter per Kelvin (W/m·K). In addition, calculating all constituent thermal resistance terms (R_{FePt}, R_{h-BN} and 2Rᵢₙₜₑᵣ) from the slope of total thermal resistance versus the number of FePt/h-BN periods (N), it is shown that the interfacial thermal resistance (ITR) of [L1₀-FePt/h-BN(002)] interfaces dominate the effective thermal resistivity of the entire superlattice structure, contributing more than 80% of it. The ITR of [L1₀-FePt/h-BN (002)] interface is approximately 6.67±0.81 m². K/GW. The high ITR of [L1₀-FePt/h-BN(002)] interfaces indicate that the FePt-(h-BN) granular film exhibits high in-plane thermal resistivity, which enables production of a high lateral thermal gradient in the media film plane to improve HAMR recording performance.

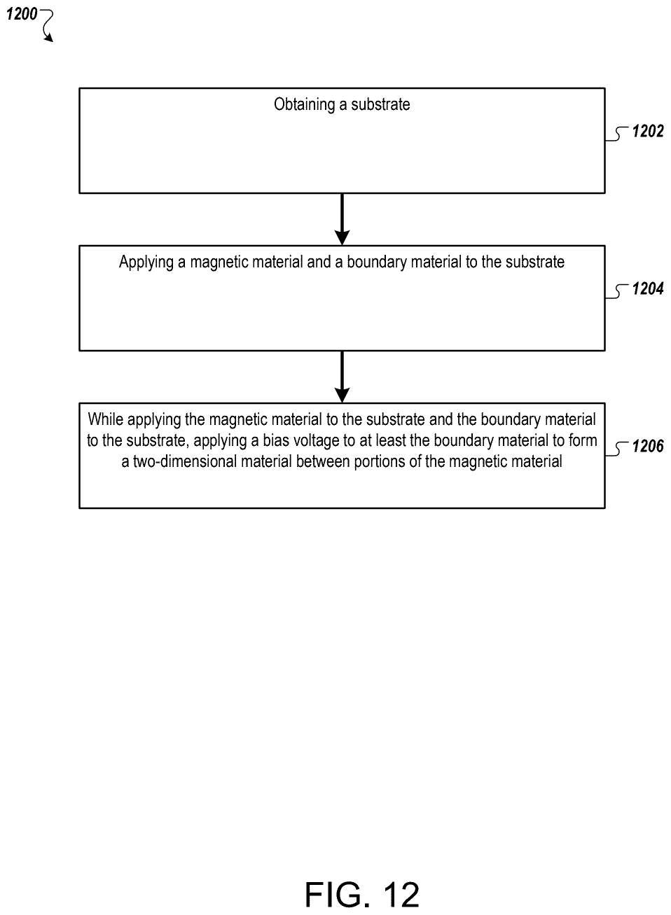

FIG. 12 illustrates a flowchart of an example method 1200 for producing 2DM materials as described herein. For clarity of presentation, the method 1200 is described in the context of the preceding figures. For example, the method 1200 can be used to generate the stack 500 or the stack 700 as described previously. The example method 1200 shown in FIG. 12 can be modified or reconfigured to include additional, fewer, or different steps (not shown in FIG. 12).

The method 1200 for forming a material includes obtaining (1202) a substrate, such as the substrates described herein. The method 1200 includes applying (1204) a magnetic material and a boundary material to the substrate. The method 1200 includes, while applying the magnetic material to the substrate and the boundary material to the substrate, applying (1206) a bias voltage to at least the boundary material to form a two-dimensional material between portions of the magnetic material. In some implementations, applying the magnetic material to the substrate and the boundary material to the substrate comprises co-sputtering the magnetic material and the boundary material onto the substrate, wherein the boundary material forms the two-dimensional material when co-sputtered onto the substrate while the bias voltage is applied.

In some implementations, method 1200 includes co-sputtering a set of layers of the magnetic material and the boundary material that forms the two-dimensional material onto the substrate, each subsequent layer after a first layer of the set of layers being co-sputtered onto a previous layer; and altering, for at least one layer, at least one sputtering condition during co-sputtering of the magnetic material and the boundary material. In some implementations, altering the at least one sputtering condition during co-sputtering of the magnetic material and the boundary material onto the substrate comprises gradually altering the at least one sputtering condition per layer as multiple layers of the magnetic material and the boundary material are co-sputtered onto the substrate.

In some implementations, the method 1200 includes gradually altering two or more sputtering conditions per layer as multiple layers of the magnetic material and the boundary material are co-sputtered onto the substrate. In some implementations, altering the at least one sputtering condition during co-sputtering of the magnetic material and the boundary material onto the substrate comprises reducing a volume % of the boundary material for at least one subsequent layer relative to the first layer. In some implementations, altering the at least one sputtering condition during co-sputtering of the magnetic material and the boundary material onto the substrate comprises reducing a volume % of the boundary material for at least one subsequent layer relative to the first layer while reducing a temperature of the substrate. In some implementations, altering the at least one sputtering condition during co-sputtering of the magnetic material and the boundary material onto the substrate comprises reducing a temperature of the substrate for at least one subsequent layer relative to the first layer.

In some implementations, the method 1200 includes applying the magnetic material and the boundary material to the substrate for a period of time without applying the bias voltage; and after the period of time, while applying the magnetic material to the substrate and the boundary material to the substrate, applying the bias voltage to at least the boundary material, wherein the boundary material comprises an amorphous material corresponding to the period of time without applying the bias voltage.

In some implementations, the method 1200 includes tuning a structure of the magnetic material based on a length of the period of time. In some implementations, the magnetic material forms columnar grains having a first diameter when the period of time is a first length of time, and wherein the magnetic material forms columnar grains having a second diameter when the period of time is a second length of time.

In some implementations, the first diameter is larger than the second diameter when the first length of time is longer than the second length of time.

In some implementations, applying the bias voltage to at least the boundary material to form the two-dimensional material between portions of the magnetic material comprises applying a direct current bias voltage.

In some implementations, applying the bias voltage to at least the boundary material to form the two-dimensional material between portions of the magnetic material comprises applying an alternative current bias voltage. In some implementations, the bias voltage is between 5 and 20 volts. In some implementations, the bias voltage is between 1 and 100 volts.

In some implementations, the method 1200 includes comprising applying a temperature to heat the magnetic material and the boundary material when applying the magnetic material and the boundary material to the substrate. In some implementations, the temperature is between 300° C. to 850° C., inclusive.

In some implementations, the temperature is reduced from a higher temperature to a lower temperature as additional magnetic material and boundary material are applied. In some implementations, the bias voltage comprises a negative substrate bias voltage with respect to a common ground connected to a sputtering chamber.

In some implementations, the method 1200 includes applying the magnetic material and the boundary material to the substrate over lithography-patterned structures.

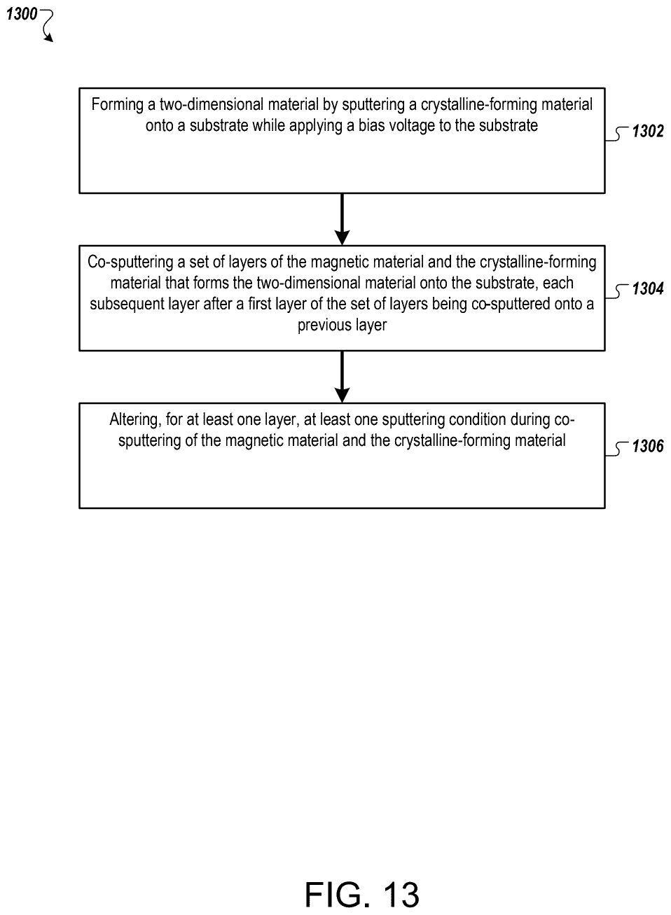

FIG. 13 illustrates a flowchart of an example method 1300 for producing 2DM materials as described herein. For clarity of presentation, the method 1300 is described in the context of the preceding figures. For example, the method 1300 can be used to generate the stack 500 or the stack 700 as described previously. The example method 1300 shown in FIG. 13 can be modified or reconfigured to include additional, fewer, or different steps (not shown in FIG. 13).

The method 1300 includes forming (1302) a two-dimensional material by sputtering a crystalline-forming material onto a substrate while applying a bias voltage to the substrate. The crystalline-forming material comprises boron nitride. The method 1300 can include co-sputtering a magnetic material and the crystalline-forming material onto the substrate, wherein the crystalline-forming material forms the two-dimensional material when co-sputtered onto the substrate while the bias voltage is applied. The method 1300 can include co-sputtering (1304) a set of layers of a magnetic material and the crystalline-forming material that forms the two-dimensional material onto the substrate, each subsequent layer after a first layer of the set of layers being co-sputtered onto a previous layer. The method 1300 can include altering (1306), for at least one layer, at least one sputtering condition during co-sputtering of the magnetic material and the crystalline-forming material.

In some implementations, the method 1300 includes altering at least one sputtering condition during sputtering of the crystalline-forming material onto the substrate. In some implementations, the at least one sputtering condition comprises a bias voltage value. In some implementations, the at least one sputtering condition comprises a temperature value of the substrate. In some implementations, the at least one sputtering condition comprises a volume % of the crystalline-forming material relative to another material being co-sputtered.

In some implementations, the method includes sputtering the crystalline-forming material onto the substrate for a period of time without applying the bias voltage; and after the period of time, applying the bias voltage to the substrate, wherein the crystalline-forming material comprises an amorphous material corresponding to the period of time without applying the bias voltage and the two-dimensional material corresponding to the period of time while applying the bias voltage.

In some implementations, the two-dimensional material comprises a hexagonal boron-nitride (h-BN) structure. In some implementations, the two-dimensional material comprises borophene. In some implementations, the two-dimensional material comprises graphene. In some implementations, the two-dimensional material comprises transition metal dichalcogenides (TMDs).

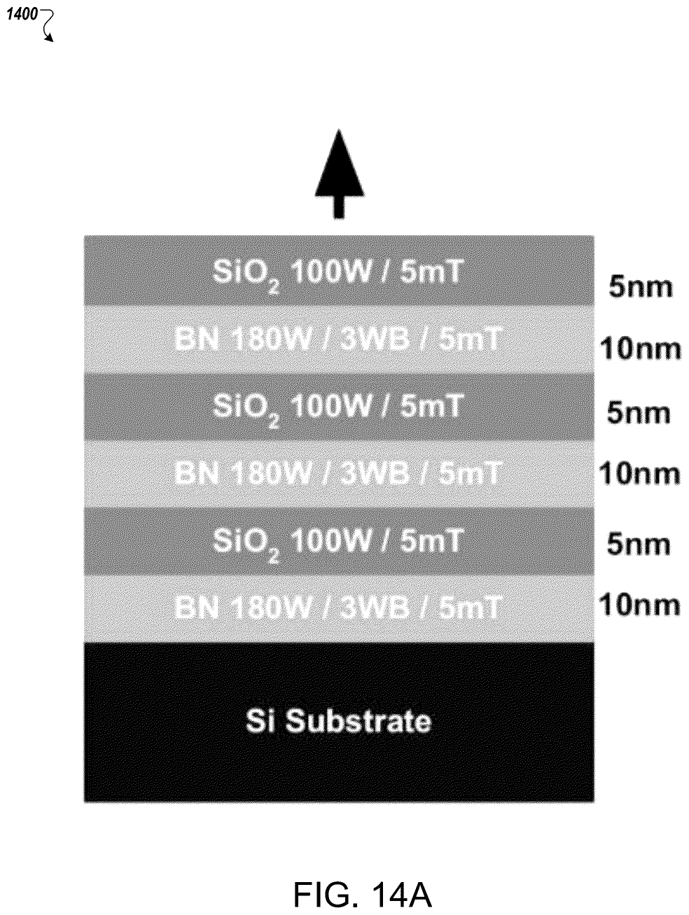

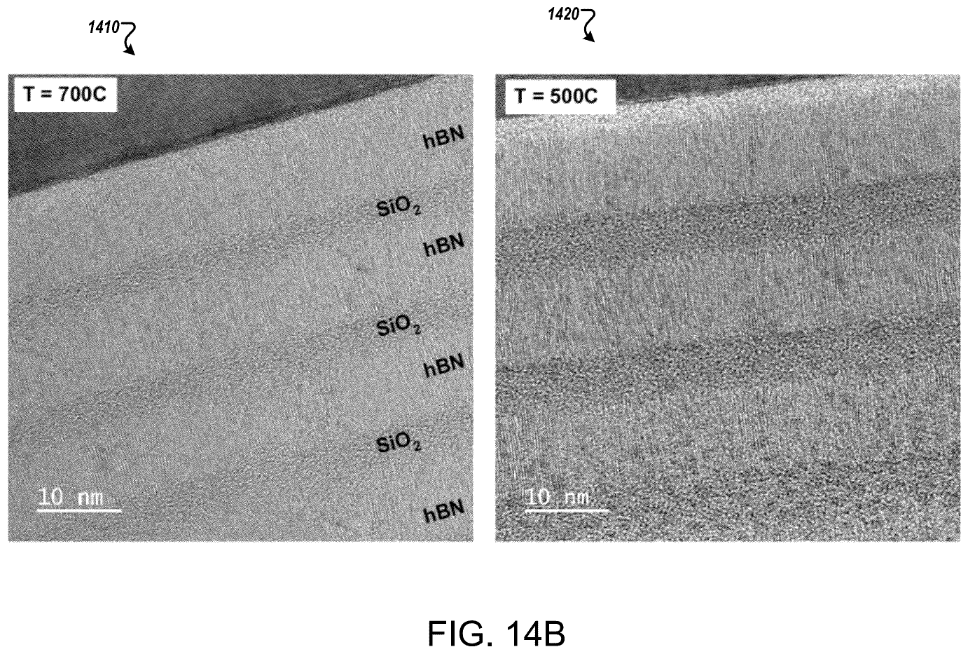

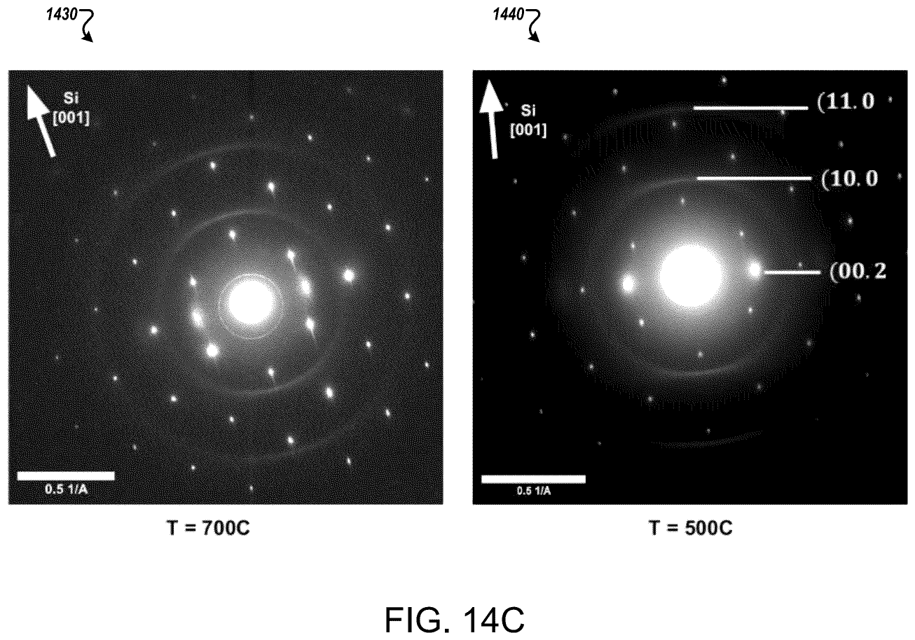

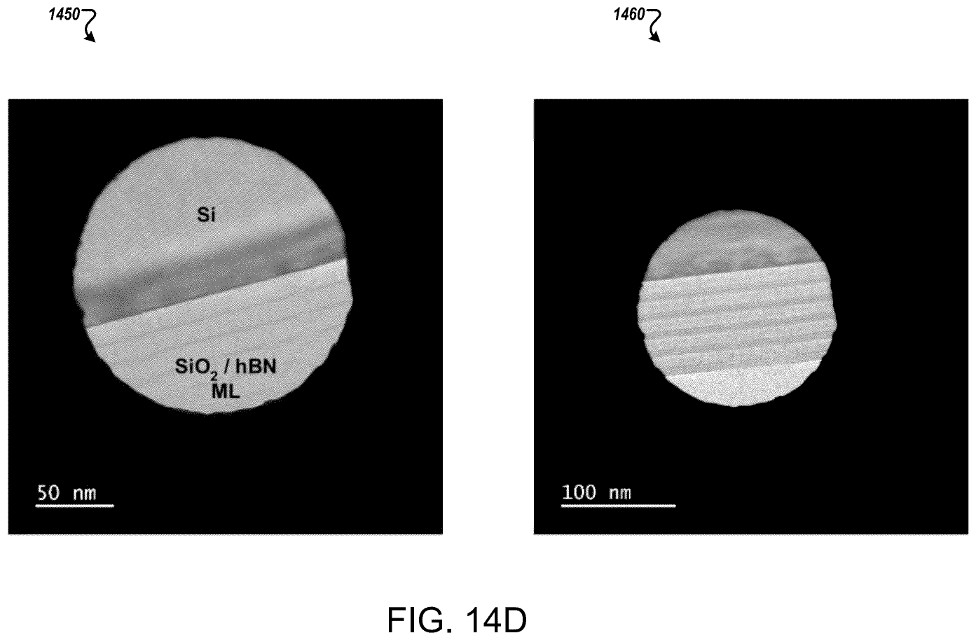

FIGS. 14A, 14B, 14C, and 14D show examples of a 2DM 1400 for use as a filler in an integrated circuit. As previously discussed, the 2DM, such as h-BN, can form a filler material in an IC. For example, planes of the 2DM in the filler can be used to conduct heat towards edges of an IC, such as to a heat sink in a package or to some other heat removal mechanism. In the stack 1400 of FIG. 14A, layers of SiO₂ are placed between layers of h-BN. The stack 1400 can be formed in accordance with the methods described herein.

As shown in FIGS. 14A-14D, the 2DM stack can be formed on a Silicon substrate, such as on an Si wafer used in forming ICs. TEM images 1410 and 1420 of FIG. 14B showing h-BN crystallization on SiO₂ underlayers with good structure at the SiO₂ interface. FIGS. 1430 and 1440 of FIG. 14C show electron diffraction patterns of the images 1410, 1420 of FIG. 14B. Images 1430, 1440 confirm the vertical texture of h-BN, which can be used to conduct heat vertically (through plane) and laterally (in-plane) if used as an interlayer dielectric for monolithic 3D ICs. These samples were prepared using the RF substrate bias as discussed herein. For these images, the temperature scan T=400° C. to 700° C. (ΔT=100° C.). Images 1450 and 1460 show additional examples of the stack 1400 at 50 nm and 100 nm, respectively.

### Examples

Multilayers or single layer of crystalline two-dimensional (2D) materials, such as hexagonal boron nitride (h-BN), borophene, graphene, transition metal dichalcogenides (TMDs) and so on, can be formed on an underlayer or substrate via sputtering or reactive sputtering techniques with moderate substrate bias, either RF or DC, at adequately high substrate temperature during material deposition.

The growth of large area single-crystal layers of 2D materials using the processes previously described can be achieved on all types of substrates or underlayers that facilitate the growth of 2D materials in sputtering, including amorphous/crystalline metals, ceramics, semiconductors, composites, etc.

The substrate bias, generated by either DC or RF sources, facilitates formation of the crystalline 2D material (2DM) atomic structures and eliminating or minimizing its amorphous phase. At the same time, the substrate temperature is adequately high for the crystalline growth. The constituent elements corresponding to the formed 2D materials can be sourced from solid sputtering targets, or a combination of solid sputtering targets and gaseous reactants (for reactive sputtering). For example, the substrate temperature during deposition may be in the range of 300° C. to 850° C., depending on the type of underlayer or substrate and the type of 2D materials. The substrate bias voltage may be in the range of 1 to 100V, or the substrate bias power may be one to two orders of magnitude lower than the target power. The substrate bias voltage is typically negative with respect to the common ground which is connected to the sputtering chamber.

With the method described previously, the first several (<10) atomic monolayers can conform to the surfaces of the underlayer or substrate, either flat or curved, during the material deposition, e.g. the h-BN layers shown in FIG. 2. The 2D materials can be formed over the lithography-patterned structures using the method described above, with monolayers conforming to the surfaces of the structures (shown in FIG. 1). The 2DM/non-2DM nanocomposite, incorporating 2D materials with other types of materials, can be formed by co-sputtering the corresponding constituent materials using either separate targets or a single composite target with the employment of the method described previously. The 2DM/2DM nanocomposite, incorporating different 2D materials, can also be formed by co-sputtering the corresponding constituent materials using either separate targets or a single composite target with the employment of the method described above.

One example of the nanocomposites formed by the method is the FePt-(h-BN) nanogranular thin film, as shown in FIG. 5C and FIG. 9A. Co-sputtering with separate FePt target and boron nitride target at substrate bias of −15V (can also be over the range of −5V to −20V) and substrate temperature 650° C. (can also be over the range of 400° C. to 850° C.) forms a planar array of FePt grains separated by layers of crystalline h-BN nanosheets perpendicular to the film plane. These h-BN nanosheets wrap around individual FePt grains conforming to the grain side surface.

To maintain desired microstructure throughout the deposited film thickness, specific parameters, including pressure, film composition, substrate bias voltage, and temperatures, are adjusted gradually during the deposition process. The graded deposition process for the FePt-2DM composite thin films enables optimized granular microstructures with columnar grains.

One example of the graded deposition process is demonstrated by the stack 500 of FIG. 5A. In the resulting film, the substrate bias voltage applied using an RF source facilitates the crystallization of 2D materials, particularly multilayer of h-BN, in grain boundaries with high deposition temperatures. Transmission electron micrographs (TEM) analysis reveals detailed nanostructures within the FePt-(h-BN) films, showcasing the effectiveness of h-BN in inhibiting lateral growth of FePt grains.

Another example of this graded deposition process is optimized to form high-aspect-ratio (>1.5) FePt grains assisted by the 2D materials in grain boundaries using bias sputtering. FIG. 7 shows the detailed film stack, combining decreasingly graded substrate temperatures with substrate bias and decremented h-BN volume fraction (24.5% to 22.6%) from bottom to top of the film. This fabrication method enables the deposition of thicker FePt-2DM films while controlling thermal budget, thereby preventing the breakdown of columnar FePt grains into smaller spherical grains.

Multilayer thin films can be fabricated, in which layers of 2D materials are separated by continuous interlayers of other materials, such as metals, oxides, or other 2D materials. Different materials, of nanometer-scale thickness, are alternately sputtered in this multilayer structure to prevent intermixing or interdiffusion, forming a superlattice microstructure with sharp interfaces. The deposition method previously described can be used to facilitate the crystallization of the 2D materials in the multilayer films.

Twisted 2DM/2DM and 2DM/non-2DM bilayers or multilayers can be formed using the method described previously. Twist angles between two interfacing layers can be engineered by tuning appropriate substrate bias and substrate temperature settings. FIG. 4A illustrates an example of two h-BN flakes which are twisted ˜2° with respect to each other resulting in the observed Moiré pattern.

One example of a multilayer film is the [FePt/h-BN(002)] multilayer thin film, as shown in FIG. 2E and FIG. 10. The multilayer film is fabricated by repeatedly and alternately sputtering FePt layer and BN layer. In each BN layer, crystalline h-BN nanosheets are formed on FePt surfaces using the bias-sputtering method described previously. Specifically, the FePt(6.5 nm) layers are DC-sputtered without bias at temperatures <100° C., while the h-BN (2.5 nm) layers are deposited at 700° C. with a substrate bias voltage of −5 to −10V generated by a RF power of 3 Watts applied to the substrate. The resulting h-BN layers exhibits 5-7 parallel h-BN atomic layers. The alternating sputtering of these two materials form a superlattice nanostructure with sharp interfaces of h-BN(002)/FePt(002). The formation of the superlattice structure with a period thickness below 10 nm can render unique physical properties, such as an ultralow thermal conductivity normal to the film.

A three-omega measurement method of thermal properties of FePt-2DM system uses the model thin films of [FePt/2DM]×N superlattice microstructure with sharp and flat interfaces. The [FePt/2DM]×N superlattice microstructure can be a good thermal and electrical insulator due to the van der Waals force bonded interfaces between FePt and 2DM. For example, the measurement results show that the [FePt/h-BN]×N superlattice microstructure has an ultra-low cross-plane thermal conductivity. The measurement results may also indicate the FePt-(h-BN) granular thin films can provide a high in-plane thermal resistance, promising for HAMR media application.

In an aspect, a material includes a magnetic material forming a plurality of grains; and a two-dimensional material between at least two grains of the plurality of grains. In some implementations including one or more of the foregoing implementations, the two-dimensional material comprises a crystalline structure. In some implementations including one or more of the foregoing implementations, the two-dimensional material comprises a single layer having the crystalline structure. In some implementations including one or more of the foregoing implementations, the two-dimensional material comprises a plurality of layers each having the crystalline structure. In some implementations including one or more of the foregoing implementations, the crystalline structure comprises a hexagonal boron-nitride (h-BN) structure. In some implementations including one or more of the foregoing implementations, a first h-BN volume fraction is reduced near a top a grain of the plurality relative to a second h-BN volume fraction near a bottom of the grain of the plurality. In some implementations including one or more of the foregoing implementations, the first h-BN volume fraction is approximately 22.6 vol % and wherein the second h-BN volume fraction is approximately 24.5 vol %. In some implementations including one or more of the foregoing implementations, the first h-BN volume fraction is approximately 16 vol % and wherein the second h-BN volume fraction is approximately 22 vol %. In some implementations including one or more of the foregoing implementations, the first h-BN volume fraction is approximately 18 vol % and wherein the second h-BN volume fraction is approximately 22 vol %. In some implementations including one or more of the foregoing implementations, the two-dimensional material comprises boron nitride and wherein the magnetic material comprises iron-platinum.

In some implementations including one or more of the foregoing implementations, the magnetic material and the two-dimensional material form a thin film having a thickness of 6.0 nanometers. In some implementations including one or more of the foregoing implementations, at least one grain of the plurality of grains has a height to diameter aspect ratio (h/D) of at least 2.5. In some implementations including one or more of the foregoing implementations, at least one grain of the plurality of grains has a height to diameter aspect ratio (h/D) of at least 1.5. In some implementations including one or more of the foregoing implementations, the plurality of grains have a center-to-center pitch distance of approximately 8.3±1.9 nm. In some implementations including one or more of the foregoing implementations, the plurality of grains have a grain areal density of roughly 1.969×10⁴ per square micrometer (μm⁻²). In some implementations including one or more of the foregoing implementations, at least one grain of the plurality of grains has a diameter of 4-10 nm and a length of at least 0.5 nm. In some implementations including one or more of the foregoing implementations, the magnetic material and the two-dimensional material form a FePt-(h-BN) thin film. In some implementations including one or more of the foregoing implementations, the magnetic material and the two-dimensional material form a FePt-(h-BN(002)) thin film. In some implementations including one or more of the foregoing implementations, the magnetic material and the two-dimensional material form a FePt-(h-BN(001)) thin film. In some implementations including one or more of the foregoing implementations, the magnetic material and the two-dimensional material form a multilayer FePt-(h-BN)×N thin film.

In some implementations including one or more of the foregoing implementations, the magnetic material forms L1₀ FePt grains. In some implementations including one or more of the foregoing implementations, the magnetic material and the two-dimensional material together have an effective thermal conductivity of 0.6±0.05 W/(mK). In some implementations including one or more of the foregoing implementations, the two-dimensional material comprises borophene. In some implementations including one or more of the foregoing implementations, the two-dimensional material comprises graphene. In some implementations including one or more of the foregoing implementations, the two-dimensional material comprises transition metal dichalcogenides (TMDs). In some implementations including one or more of the foregoing implementations, the two-dimensional material forms at least 4 to 6 nanosheets that conform to at least one grain of the plurality of grains. In some implementations including one or more of the foregoing implementations, the two-dimensional material forms at least 6 to 8 nanosheets that conform to at least one grain of the plurality of grains. In some implementations including one or more of the foregoing implementations, the two-dimensional material forms up to 10 nanosheets that conform to at least one grain of the plurality of grains.

In some implementations including one or more of the foregoing implementations, the material includes an underlayer selected from: MgO (001), Cr (001), and amorphous Ta (a-Ta).

In some implementations including one or more of the foregoing implementations, the material includes a nucleation layer of magnetic material onto which the plurality of grains and the two-dimensional material between the grains are formed.

In some implementations including one or more of the foregoing implementations, the plurality of grains and the two-dimensional material form a FePt-(h-BN) film that is at least 5 nm tall, wherein grains of the plurality of grains comprise unbroken, columnar grains, and wherein the two-dimensional material comprises one or more nanosheets that conform the grains of the plurality of grains.

In some implementations including one or more of the foregoing implementations, the material includes a plurality of layers of the magnetic material and the two-dimensional material. In some implementations including one or more of the foregoing implementations, at least two layers of the plurality of layers are twisted with respect to each other. In some implementations including one or more of the foregoing implementations, the at least two layers of the plurality of layers are twisted at approximately 2° with respect to each other.

In some implementations including one or more of the foregoing implementations, the magnetic material and the two-dimensional material form a superlattice nanostructure with sharp interfaces of h-BN(002)/FePt(002).

In some implementations including one or more of the foregoing implementations, the material includes a substrate on which the magnetic material and the two-dimensional material are sputtered. In some implementations including one or more of the foregoing implementations, the substrate is curved. In some implementations including one or more of the foregoing implementations, the substrate is selected from one of an amorphous metal, a crystalline metal, a ceramic, a semiconductor, and a composite.

In some implementations including one or more of the foregoing implementations, the magnetic material comprises FePt.

In some implementations including one or more of the foregoing implementations, the material includes a substrate comprising one or more lithography-patterned structures, wherein the magnetic material and the two-dimensional material are applied to the lithography-patterned structures.

In an aspect, a memory is formed from the material of any of the foregoing implementations or aspects. In some implementations including one or more of the foregoing implementations, the memory comprises a magnetoresistive random access memory (MRAM). In some implementations including one or more of the foregoing implementations, the memory comprises a perpendicular spin transfer torque (STT) MRAM memory element.

In an aspect, a process for forming a material includes obtaining a substrate; applying a magnetic material and a boundary material to the substrate; and while applying the magnetic material to the substrate and the boundary material to the substrate, applying a bias voltage to at least the boundary material to form a two-dimensional material between portions of the magnetic material.

In some implementations including one or more of the foregoing implementations, applying the magnetic material to the substrate and the boundary material to the substrate comprises co-sputtering the magnetic material and the boundary material onto the substrate, wherein the boundary material forms the two-dimensional material when co-sputtered onto the substrate while the bias voltage is applied.

In some implementations including one or more of the foregoing implementations, the process includes co-sputtering a set of layers of the magnetic material and the boundary material that forms the two-dimensional material onto the substrate, each subsequent layer after a first layer of the set of layers being co-sputtered onto a previous layer; and altering, for at least one layer, at least one sputtering condition during co-sputtering of the magnetic material and the boundary material. In some implementations including one or more of the foregoing implementations, altering the at least one sputtering condition during co-sputtering of the magnetic material and the boundary material onto the substrate comprises gradually altering the at least one sputtering condition per layer as multiple layers of the magnetic material and the boundary material are co-sputtered onto the substrate.

In some implementations including one or more of the foregoing implementations, the process includes gradually altering two or more sputtering conditions per layer as multiple layers of the magnetic material and the boundary material are co-sputtered onto the substrate.

In some implementations including one or more of the foregoing implementations, altering the at least one sputtering condition during co-sputtering of the magnetic material and the boundary material onto the substrate comprises reducing a volume % of the boundary material for at least one subsequent layer relative to the first layer.

In some implementations including one or more of the foregoing implementations, altering the at least one sputtering condition during co-sputtering of the magnetic material and the boundary material onto the substrate comprises reducing a volume % of the boundary material for at least one subsequent layer relative to the first layer while reducing a temperature of the substrate.

In some implementations including one or more of the foregoing implementations, altering the at least one sputtering condition during co-sputtering of the magnetic material and the boundary material onto the substrate comprises reducing a temperature of the substrate for at least one subsequent layer relative to the first layer.

In some implementations including one or more of the foregoing implementations, the process includes applying the magnetic material and the boundary material to the substrate for a period of time without applying the bias voltage; and after the period of time, while applying the magnetic material to the substrate and the boundary material to the substrate, applying the bias voltage to at least the boundary material. In some implementations including one or more of the foregoing implementations, the boundary material includes an amorphous material corresponding to the period of time without applying the bias voltage.

In some implementations including one or more of the foregoing implementations, the process includes tuning a structure of the magnetic material based on a length of the period of time. In some implementations including one or more of the foregoing implementations, the magnetic material forms columnar grains having a first diameter when the period of time is a first length of time, and wherein the magnetic material forms columnar grains having a second diameter when the period of time is a second length of time. In some implementations including one or more of the foregoing implementations, the first diameter is larger than the second diameter when the first length of time is longer than the second length of time.

In some implementations including one or more of the foregoing implementations, applying the bias voltage to at least the boundary material to form the two-dimensional material between portions of the magnetic material comprises applying a direct current bias voltage.

In some implementations including one or more of the foregoing implementations, applying the bias voltage to at least the boundary material to form the two-dimensional material between portions of the magnetic material comprises applying an alternative current bias voltage.

In some implementations including one or more of the foregoing implementations, the bias voltage is between 5 and 20 volts. In some implementations including one or more of the foregoing implementations, the bias voltage is between 1 and 100 volts.

In some implementations including one or more of the foregoing implementations, the process includes applying a temperature to heat the magnetic material and the boundary material when applying the magnetic material and the boundary material to the substrate.

In some implementations including one or more of the foregoing implementations, the temperature is between 300° C. to 850° C., inclusive. In some implementations including one or more of the foregoing implementations, the temperature is reduced from a higher temperature to a lower temperature as additional magnetic material and boundary material are applied. In some implementations including one or more of the foregoing implementations, the bias voltage comprises a negative substrate bias voltage with respect to a common ground connected to a sputtering chamber.

In some implementations including one or more of the foregoing implementations, the process includes applying the magnetic material and the boundary material to the substrate over lithography-patterned structures.

In an aspect, a material includes a length material forming a structure; and a two-dimensional material proximate to the length of the material conducting metal forming the structure. In some implementations including one or more of the foregoing implementations, the structure includes a wire. In some implementations including one or more of the foregoing implementations, the wire is part of an integrated circuit (IC).

In some implementations including one or more of the foregoing implementations, the material includes a substrate comprising one or more lithography-patterned structures including the structure, the two-dimensional material is applied to the lithography-patterned structures. In some implementations including one or more of the foregoing implementations, the substrate is part of an integrated circuit (IC). In some implementations including one or more of the foregoing implementations, the two-dimensional material comprises a crystalline structure. In some implementations including one or more of the foregoing implementations, the two-dimensional material comprises a single layer having the crystalline structure. In some implementations including one or more of the foregoing implementations, the two-dimensional material comprises a plurality of layers each having the crystalline structure. In some implementations including one or more of the foregoing implementations, the crystalline structure comprises a hexagonal boron-nitride (h-BN) structure.

In some implementations including one or more of the foregoing implementations, the two-dimensional material comprises borophene. In some implementations including one or more of the foregoing implementations, the two-dimensional material comprises graphene. In some implementations including one or more of the foregoing implementations, the two-dimensional material comprises transition metal dichalcogenides (TMDs).

In an aspect, a process includes forming a two-dimensional material by sputtering a crystalline-forming material onto a substrate while applying a bias voltage to the substrate.

In some implementations including one or more of the foregoing implementations, the crystalline-forming material comprises boron nitride.

In some implementations including one or more of the foregoing implementations, the process includes co-sputtering a magnetic material and the crystalline-forming material onto the substrate, wherein the crystalline-forming material forms the two-dimensional material when co-sputtered onto the substrate while the bias voltage is applied.

In some implementations including one or more of the foregoing implementations, the process includes co-sputtering a set of layers of a magnetic material and the crystalline-forming material that forms the two-dimensional material onto the substrate, each subsequent layer after a first layer of the set of layers being co-sputtered onto a previous layer; and altering, for at least one layer, at least one sputtering condition during co-sputtering of the magnetic material and the crystalline-forming material.

In some implementations including one or more of the foregoing implementations, the process includes altering at least one sputtering condition during sputtering of the crystalline-forming material onto the substrate.

In some implementations including one or more of the foregoing implementations, the at least one sputtering condition comprises a bias voltage value.

In some implementations including one or more of the foregoing implementations, the at least one sputtering condition comprises a temperature value of the substrate.

In some implementations including one or more of the foregoing implementations, the at least one sputtering condition comprises a volume % of the crystalline-forming material relative to another material being co-sputtered.

In some implementations including one or more of the foregoing implementations, the process includes sputtering the crystalline-forming material onto the substrate for a period of time without applying the bias voltage; and after the period of time, applying the bias voltage to the substrate, wherein the crystalline-forming material comprises an amorphous material corresponding to the period of time without applying the bias voltage and the two-dimensional material corresponding to the period of time while applying the bias voltage.

In some implementations including one or more of the foregoing implementations, the two-dimensional material comprises a hexagonal boron-nitride (h-BN) structure. In some implementations including one or more of the foregoing implementations, the two-dimensional material comprises borophene. In some implementations including one or more of the foregoing implementations, the two-dimensional material comprises graphene. In some implementations including one or more of the foregoing implementations, the two-dimensional material comprises transition metal dichalcogenides (TMDs).

In an aspect, an integrated circuit includes a plurality of wires; and a filler material among the wires of the plurality of wires, the filler material comprising a two-dimensional material configured to conduct heat away from the wires.

The In some implementations including one or more of the foregoing implementations, the IC includes a substrate having an edge, wherein the two-dimensional material comprises one or more crystalline sheets, and wherein the crystalline sheets are oriented to conduct heat away from the wires to the edge of the substrate.

In some embodiments, the described herein may be monolithically integrated with integrated circuits, or as stand-alone high storage capacity memory chips.

Various components may be described as performing a task or tasks, for convenience in the description. Such descriptions should be interpreted as including the phrase “configured to.” Reciting a component that is configured to perform one or more tasks is expressly intended not to invoke 35 U.S.C. § 112(f) interpretation for that component.

The foregoing description of one or more implementations provides illustration and description but is not intended to be exhaustive or to limit the scope of embodiments to the precise form disclosed. Modifications and variations are possible in light of the above teachings or may be acquired from practice of various embodiments.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A material comprising:
a magnetic material forming a plurality of grains; and
a two-dimensional material between at least two grains of the plurality of grains.

2. The material of claim 1, wherein the two-dimensional material comprises a single layer having a crystalline structure.

3. The material of claim 1, wherein the two-dimensional material comprises a plurality of layers each having a crystalline structure.

4. The material of claim 1, wherein the two-dimensional material comprises a hexagonal boron-nitride (h-BN) structure and wherein the magnetic material comprises iron-platinum.

5. The material of claim 4, wherein a first h-BN volume fraction is reduced near a top a grain of the plurality relative to a second h-BN volume fraction near a bottom of the grain of the plurality, and wherein the first h-BN volume fraction is approximately 16-22.6 vol % and wherein the second h-BN volume fraction is approximately 22-24.5 vol %.

6. The material of claim 1, wherein the magnetic material and the two-dimensional material form a thin film having a thickness of less than 6.0 nanometers, wherein at least one grain of the plurality of grains has a height to diameter aspect ratio (h/D) of at least 2.5, wherein the plurality of grains have a center-to-center pitch distance of approximately 8.3±1.9 nm, or wherein the plurality of grains have a grain areal density of roughly 1.969×10⁴ per square micrometer (μm⁻²).

7. The material of claim 1, wherein the magnetic material and the two-dimensional material form a multilayer FePt-(h-BN)×N thin film.

8. The material of claim 1, wherein the magnetic material forms L1₀ FePt grains.

9. The material of claim 1, wherein the magnetic material and the two-dimensional material together have an effective thermal conductivity of 0.6±0.05 W/(mK).

10. The material of claim 1, wherein the two-dimensional material comprises borophene, graphene, or transition metal dichalcogenides (TMDs).

11. The material of claim 1, wherein the two-dimensional material forms at least 4 to 10 nanosheets that conform to at least one grain of the plurality of grains.

12. The material of claim 1, wherein the plurality of grains and the two-dimensional material form a FePt-(h-BN) film that is at least 5 nm tall, wherein grains of the plurality of grains comprise unbroken, columnar grains, and wherein the two-dimensional material comprises one or more nanosheets that conform the grains of the plurality of grains.

13. A method for forming a material, the method comprising:
obtaining a substrate;
applying a magnetic material and a boundary material to the substrate; and
while applying the magnetic material to the substrate and the boundary material to the substrate, applying a bias voltage to at least the boundary material to form a two-dimensional material between portions of the magnetic material.

14. The method of claim 13, wherein applying the magnetic material to the substrate and the boundary material to the substrate comprises co-sputtering the magnetic material and the boundary material onto the substrate, wherein the boundary material forms the two-dimensional material when co-sputtered onto the substrate while the bias voltage is applied.

15. The method of claim 13, further comprising:
co-sputtering a set of layers of the magnetic material and the boundary material that forms the two-dimensional material onto the substrate, each subsequent layer after a first layer of the set of layers being co-sputtered onto a previous layer; and
altering, for at least one layer, at least one sputtering condition during co-sputtering of the magnetic material and the boundary material.

16. The method of claim 15, wherein altering the at least one sputtering condition during co-sputtering of the magnetic material and the boundary material onto the substrate comprises gradually altering the at least one sputtering condition per layer as multiple layers of the magnetic material and the boundary material are co-sputtered onto the substrate.

17. The method of claim 16, further comprising gradually altering two or more sputtering conditions per layer as multiple layers of the magnetic material and the boundary material are co-sputtered onto the substrate.

18. The method of claim 17, wherein altering the at least one sputtering condition during co-sputtering of the magnetic material and the boundary material onto the substrate comprises reducing a volume % of the boundary material for at least one subsequent layer relative to the first layer, or
wherein altering the at least one sputtering condition during co-sputtering of the magnetic material and the boundary material onto the substrate comprises reducing a volume % of the boundary material for at least one subsequent layer relative to the first layer while reducing a temperature of the substrate.

19. The method of claim 17, wherein altering the at least one sputtering condition during co-sputtering of the magnetic material and the boundary material onto the substrate comprises reducing a temperature of the substrate for at least one subsequent layer relative to the first layer.

20. The method of claim 13, further comprising:
applying the magnetic material and the boundary material to the substrate for a period of time without applying the bias voltage; and
after the period of time, while applying the magnetic material to the substrate and the boundary material to the substrate, applying the bias voltage to at least the boundary material,
wherein the boundary material comprises an amorphous material corresponding to the period of time without applying the bias voltage.
